(19) United States
(12) Patent Application Publication
(10) Pub. No.: US 2024/0373635 A1
(43) Pub. Date: Nov. 7, 2024

(54) SEMICONDUCTOR DEVICES AND DATA STORAGE SYSTEMS INCLUDING THE SAME

(71) Applicant: SAMSUNG ELECTRONICS CO., LTD., Suwon-si (KR)

(72) Inventors: Dongsung CHOI, Suwon-si (KR); Byongju KIM, Suwon-si (KR); Hyungjoon KIM, Suwon-si (KR)

(21) Appl. No.: 18/587,785

(22) Filed: Feb. 26, 2024

(30) Foreign Application Priority Data
May 4, 2023 (KR) 10-2023-0058394

(51) Int. Cl. H10B 43/27; H10B 41/27; H10B 41/35; H10B 43/35

(52) U.S. Cl. CPC H10B 43/27; H10B 41/27; H10B 41/35; H10B 43/35

(57) ABSTRACT

A semiconductor device includes a plate layer, gate electrodes on the plate layer, interlayer insulating layers that are alternately stacked with the gate electrodes, and channel structure that extends into the gate electrodes, where the channel structure includes a channel filling layer, a channel layer that at least partially surrounds the channel filling layer, charge storage layers between the gate electrodes and the channel layer, a first dielectric layer between the gate electrodes and the charge storage layers, and a second dielectric layer between the channel layer and the charge storage layers, where the channel layer includes first convex portions that extend toward the channel filling layer from a side surface of the channel layer that contacts the channel filling layer, and where vertices of the first convex portions are at first levels in the first direction that are between each level of a pair of adjacent gate electrodes.

### CROSS-REFERENCE TO RELATED APPLICATION(S)

This application claims benefit of priority to Korean Patent Application No. 10-2023-0058394 filed on May 4, 2023 in the Korean Intellectual Property Office, the disclosure of which is incorporated herein by reference in its entirety.

### TECHNICAL FIELD

Example embodiments of the present disclosure relate to a semiconductor device and a data storage system including the same.

### BACKGROUND

A semiconductor device may store high-capacity data in a data storage system. Accordingly, a method for increasing data storage capacity of a semiconductor device may be desired. For example, a semiconductor device including memory cells disposed three-dimensionally, instead of memory cells disposed two-dimensionally, may have increased data storage capacity.

### SUMMARY

An example embodiment of the present disclosure is to provide a semiconductor device having improved reliability.

An example embodiment of the present disclosure is to provide a data storage system including a semiconductor device having improved reliability.

According to an example embodiment of the present disclosure, a semiconductor device includes a plate layer; gate electrodes that are on the plate layer, extend in a first direction that is perpendicular to an upper surface of the plate layer, and are spaced apart from each other; interlayer insulating layers that are alternately stacked with the gate electrodes on the plate layer; and a channel structure that extends into the gate electrodes and in the first direction, where the channel structure includes a channel filling layer that extends in the first direction, a channel layer that at least partially surrounds the channel filling layer, charge storage layers that are between the gate electrodes and the channel layer and spaced apart from each other in the first direction, a first dielectric layer between the gate electrodes and the charge storage layers, and a second dielectric layer between the channel layer and the charge storage layers, where the channel layer includes first convex portions that extend toward the channel filling layer from a side surface of the channel layer that contacts the channel filling layer, and where vertices of the first convex portions are at first levels in the first direction that are between each level of a pair of adjacent gate electrodes in the first direction.

According to an example embodiment of the present disclosure, a semiconductor device includes a plate layer; gate electrodes that are on the plate layer, extend in a first direction that is perpendicular to an upper surface of the plate layer, and are spaced apart from each other; interlayer insulating layers that are alternately stacked with the gate electrodes on the plate layer; and a channel structure that extends into the gate electrodes and in the first direction, where the channel structure includes a channel filling layer, a channel layer on the channel filling layer, a second dielectric layer on the channel layer, charge storage layers on the second dielectric layer, and first dielectric layers on the charge storage layers, and where the channel filling layer includes curved portions that extend toward the channel layer, and where a first level of a first curved portion of the curved portions is at a same level as an upper end of a first interlayer insulating layer of the interlayer insulating layers, and where a second level of a second curved portion of the curved portions is at a same level as a lower end of the first interlayer insulating layer the interlayer insulating layers.

According to an example embodiment of the present disclosure, a data storage system includes a first semiconductor structure, a second semiconductor structure on the first semiconductor structure, and an input/output pad electrically connected to the first semiconductor structure; and a controller connected to the semiconductor storage device through the input/output pad, where the second semiconductor structure includes: a plate layer; gate electrodes that are on the plate layer, extend in a first direction that is perpendicular to an upper surface of the plate layer, and are spaced apart from each other; interlayer insulating layers that are alternately stacked with the gate electrodes on the plate layer; and a channel structure that extends into the gate electrodes and in the first direction, where the channel structure includes a channel filling layer, a channel layer on the channel filling layer, a second dielectric layer on the channel layer, charge storage layers on the second dielectric layer, and first dielectric layers on the charge storage layers, where the channel layer includes convex portions that extend toward the channel filling layer from a side surface of the channel layer, and where vertices of the convex portions are at first levels in the first direction that are levels between each level of a pair of adjacent gate electrodes in the first direction.

### BRIEF DESCRIPTION OF DRAWINGS

The above and other aspects, features, and advantages of the present disclosure will be more clearly understood from the following detailed description, taken in combination with the accompanying drawings, in which:

FIG. 1 is a plan view illustrating a semiconductor device according to an example embodiment of the present disclosure;

FIG. 2 is a cross-sectional view illustrating a semiconductor device according to an example embodiment of the present disclosure;

FIGS. 3A and 3B are enlarged views illustrating partial regions of a semiconductor device according to an example embodiment of the present disclosure;

FIGS. 4A and 4B are enlarged views illustrating a semiconductor device according to an example embodiment of the present disclosure;

FIG. 5 is a cross-sectional view illustrating a semiconductor device according to an example embodiment of the present disclosure;

FIGS. 6A and 6B are cross-sectional views illustrating a semiconductor device according to an example embodiment of the present disclosure;

FIGS. 7, 8A, 9A, 10A, 11A, 12A, 13A, 14, 15, and 16 are cross-sectional views a method of manufacturing a semiconductor device according to an example embodiment of the present disclosure;

FIGS. 8B, 9B, 10B, 11B, 12B, and 13B are cross-sectional views a method of manufacturing a semiconductor device according to an example embodiment of the present disclosure;

FIG. 17 is a view illustrating a data storage system including a semiconductor device according to an example embodiment of the present disclosure;

FIG. 18 is a perspective view illustrating a data storage system including a semiconductor device according to an example embodiment of the present disclosure; and

FIG. 19 is a cross-sectional view illustrating a semiconductor package according to an example embodiment of the present disclosure.

### DETAILED DESCRIPTION

To clarify the present disclosure, parts that are not connected with the description will be omitted, and the same elements or equivalents are referred to by the same reference numerals throughout the specification. Further, since sizes and thicknesses of constituent members shown in the accompanying drawings are arbitrarily given for better understanding and ease of description, the present disclosure is not limited to the illustrated sizes and thicknesses. In the drawings, the thickness of layers, films, panels, regions, etc., are exaggerated for clarity. In the drawings, for better understanding and ease of description, thicknesses of some layers and areas are excessively displayed.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, spatially relative terms, such as “beneath,” “below,” “lower,” “above,” “upper,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations), and the spatially relative descriptors used herein may be interpreted accordingly.

In addition, unless explicitly described to the contrary, the word “comprises”, and variations such as “comprises” or “comprising”, will be understood to imply the inclusion of stated elements but not the exclusion of any other elements. As used herein, the phrase “at least one of A, B, and C” refers to a logical (A OR B OR C) using a non-exclusive logical OR, and should not be construed to mean “at least one of A, at least one of B and at least one of C.” As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, steps, operations, elements and/or components, but do not preclude the presence or addition of one or more other features, steps, operations, elements, components and/or groups thereof. The term “and/or” includes any and all combinations of one or more of the associated listed items. As used herein, “an element A is at a same level as element B” refers to at least one surface of element A that is coplanar with at least one surface of element B. The term “connected” may be used herein to refer to a physical and/or electrical connection and may refer to a direct or indirect physical and/or electrical connection. The phrase “an element A fills element B” may refer to element A being at least partially within a space defined by element B.

Hereinafter, embodiments of the present disclosure will be described as follows with reference to the accompanying drawings.

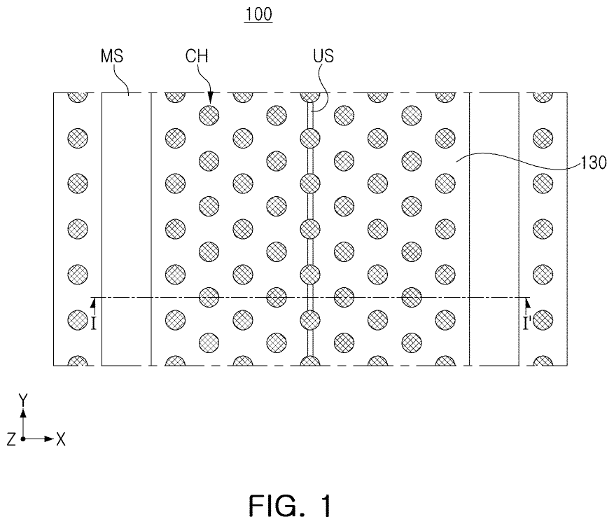

FIG. 1 is a plan view illustrating a semiconductor device according to an example embodiment.

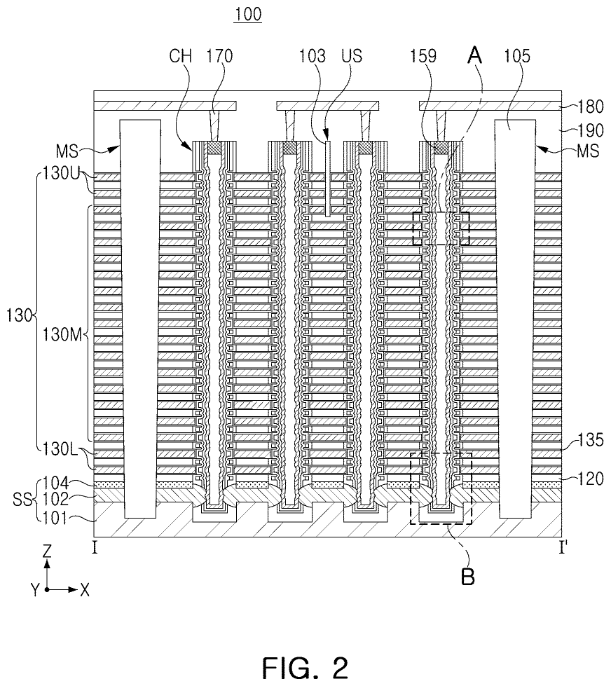

FIG. 2 is a cross-sectional view illustrating a semiconductor device according to an example embodiment.

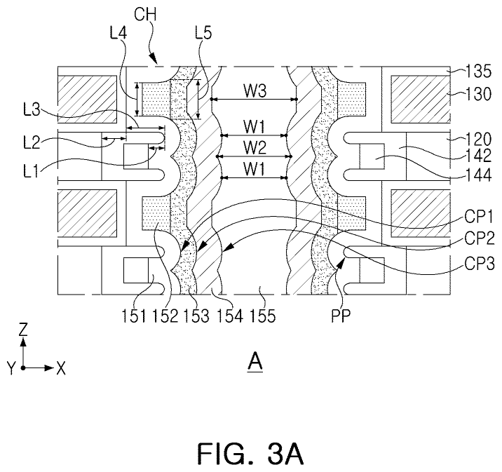

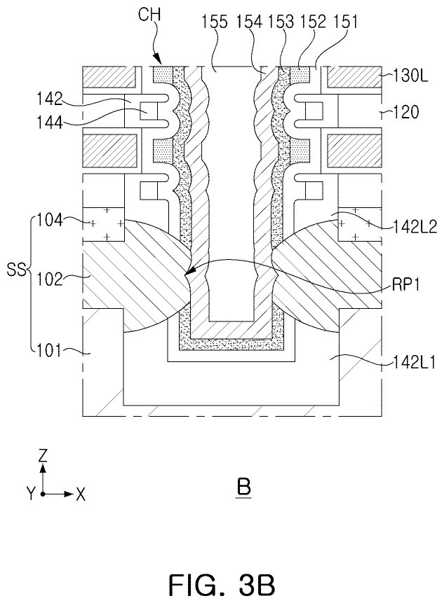

FIGS. 3A and 3B are enlarged views illustrating partial regions of a semiconductor device according to an example embodiment. FIG. 3A illustrates region “A” in FIG. 2, and FIG. 3B illustrates region “B” in FIG. 2.

Referring to FIGS. 1 to 3B, a semiconductor device 100 may include a source structure SS, gate electrodes 130 stacked on the source structure SS, interlayer insulating layers 120 alternately stacked with the gate electrodes 130, channel structures CH that extend through a stack structure of gate electrodes 130, gate isolation regions MS that extend through gate electrodes 130, upper isolation regions US that extend through a portion in the upper portion of gate electrodes 130, studs 170 on the channel structures CH, and bit lines 180 on the studs 170. The semiconductor device 100 further may include first and second insulating layers 142 and 144 disposed in parallel with the interlayer insulating layers 120, gate dielectric layers 135 surrounding the gate electrodes 130, and a cell region insulating layer 190 covering or overlapping a stack structure of the gate electrodes 130.

The source structure SS may include a plate layer 101, a first horizontal conductive layer 102, and a second horizontal conductive layer 104 that are sequentially stacked. However, in example embodiments, the number of conductive layers included in the source structure SS may be varied.

The plate layer 101 may have a plate shape and may function as at least a portion of a common source line of the semiconductor device 100. The plate layer 101 may have an upper surface extending in the X-direction and the Y-direction. The plate layer 101 may include a conductive material. For example, the plate layer 101 may include a semiconductor material, such as a group IV semiconductor, a group III-V compound semiconductor, or a group II-VI compound semiconductor. For example, a group IV semiconductor may include silicon, germanium, or silicon-germanium. The plate layer 101 may further include impurities. The plate layer 101 may be provided as a polycrystalline semiconductor layer such as a polycrystalline silicon layer or an epitaxial layer.

The first and second horizontal conductive layers 102 and 104 may be sequentially stacked on the upper surface of the plate layer 101. The first horizontal conductive layer 102 may function as a portion of a common source line of the semiconductor device 100, and may function as a common source line together with the plate layer 101, for example.

As illustrated in FIG. 3B, the first horizontal conductive layer 102 may be directly connected to the channel layer 154 and surround the channel layer 154. The first horizontal conductive layer 102 may have a shape such that it may be vertically recessed into a first lower insulating layer 142L1 and a first upper insulating layer 142L2, and may be horizontally recessed into the first dielectric layer 151 and the second dielectric layer 153. The first horizontal conductive layer 102 may have a recess portion RP1 or an inwardly curved portion (e.g., concave portion) in a central region in the Z-direction in a region in contact with the channel layer 154. The recess portion RP1 may also be described as a protrusion portion of the channel layer 154 in which the channel layer 154 may extend toward the first horizontal conductive layer 102. However, in example embodiments, the shape of a region of the first horizontal conductive layer 102 in contact with the channel layer 154 may vary in other embodiments.

The first and second horizontal conductive layers 102 and 104 may include a semiconductor material, for example, polycrystalline silicon. In this case, at least the first horizontal conductive layer 102 may be a layer doped with impurities of the same conductivity-type as that of the plate layer 101, and the second horizontal conductive layer 104 may be a doped layer or may include impurities diffused from the first horizontal conductive layer 102. However, the material of the second horizontal conductive layer 104 is not limited to a semiconductor material, and may be replaced with an insulating layer.

The gate electrodes 130 may be vertically stacked and spaced apart from each other on the plate layer 101 and may form a stack structure together with the interlayer insulating layers 120. The gate electrodes 130 may include upper gate electrodes 130U forming string select transistors, memory gate electrodes 130M forming a plurality of memory cells, and lower gate electrodes 130L forming a ground select transistor. The number of memory gate electrodes 130M included in the memory cells may be determined according to capacity of the semiconductor device 100. In the example embodiment, each of the upper gate electrodes 130U and the lower gate electrodes 130L may include two gate electrodes. However, in example embodiments, the number of the upper gate electrodes 130U and the number of the lower gate electrodes 130L may be one to four or more. In some example embodiments, the gate electrodes 130 may further include a gate electrode forming an erase transistor adjacent to upper gate electrodes 130U and/or lower gate electrodes 130L and used for an erase operation using a gate induced drain leakage (GIDL) phenomenon. A portion of the gate electrodes 130, for example, memory gate electrode 130M adjacent to the upper gate electrodes 130U and/or the lower gate electrodes 130L, may be a dummy gate electrode.

The gate electrodes 130 may be vertically stacked and spaced apart from each other on the plate layer 101, and may be spaced apart from each other in the X-direction by isolation regions MS extending in the Y-direction. The gate electrodes 130 between a pair of isolation regions MS may form a memory block, but the range of the memory block is not limited thereto. A portion of the gate electrodes 130, for example, the memory gate electrodes 130M may form a layer in a memory block.

The gate electrodes 130 may include a metal material, such as tungsten (W). In example embodiments, the gate electrodes 130 may include polycrystalline silicon or a metal silicide material. In example embodiments, the gate electrodes 130 may further include a diffusion barrier on an external side. For example, the diffusion barrier may include tungsten nitride (WN), tantalum nitride (TaN), titanium nitride (TiN), or a combination thereof.

The gate dielectric layers 135 may surround the gate electrodes 130, respectively. The gate dielectric layers 135 may cover/overlap an upper surface, a lower surface, and side surfaces opposing the channel structures CH of the gate electrodes 130. Here, the gate dielectric layers 135 may include an insulating material, for example, silicon oxide (SiO₂), silicon nitride (Si₃N₄), silicon oxynitride (SiON), a high-K material or a combination thereof. The high-K material may refer to a dielectric material having a dielectric constant higher than that of silicon oxide (SiO₂). The high-K material may include, for example, aluminum oxide (Al₂O₃), tantalum oxide (Ta₂O₃), titanium oxide (TiO₂), yttrium oxide (Y₂O₃), zirconium oxide (ZrO₂), zirconium silicon oxide (ZrSiₓO_{y}), hafnium oxide (HfO₂), hafnium silicon oxide (HfSiₓO_{y}), lanthanum oxide (La₂O₃), lanthanum aluminum oxide (LaAlₓO_{y}), lanthanum hafnium oxide (LaHfₓO_{y}), hafnium aluminum oxide (HfAlₓO_{y}), and prascodymium oxide (Pr₂O₃) or a combination thereof.

The interlayer insulating layers 120 may be between the gate electrodes 130. The interlayer insulating layers 120 may contact the gate dielectric layers 135 between the gate electrodes 130. Similarly to the gate electrodes 130, the interlayer insulating layers 120 may also be spaced apart from each other in a direction perpendicular to an upper surface of the plate layer 101. A portion of the interlayer insulating layers 120 may have different thicknesses. The interlayer insulating layers 120 may have substantially flat upper and lower surfaces. The interlayer insulating layers 120 may include an insulating material such as silicon oxide or silicon nitride. For example, the interlayer insulating layers 120 may be silicon oxide including hydrogen (H) as impurities. A concentration of hydrogen (H) of the interlayer insulating layer 120 may be greater than a concentration of hydrogen (H) of the first insulating layer 142. Also, for example, the interlayer insulating layer 120 may have a higher oxygen: silicon ratio than that of the first insulating layer 142 and may have a relatively higher oxygen ratio than SiO₂.

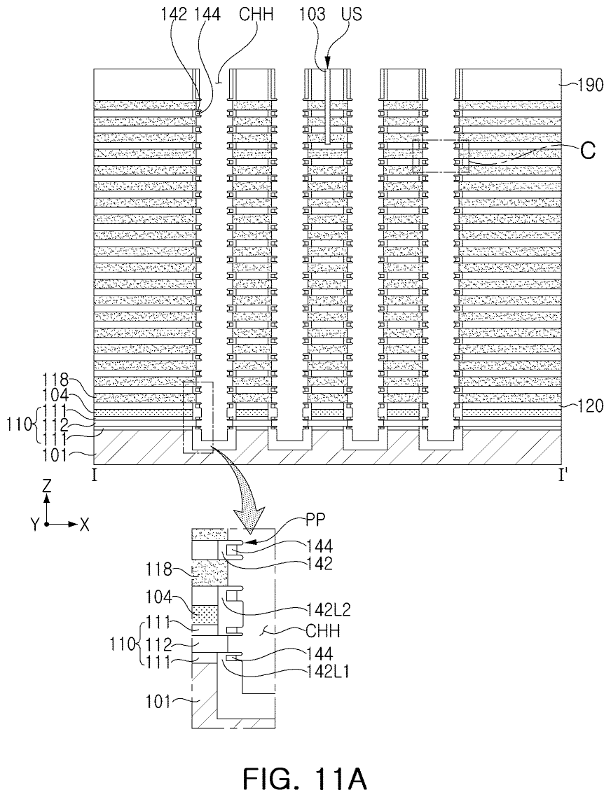

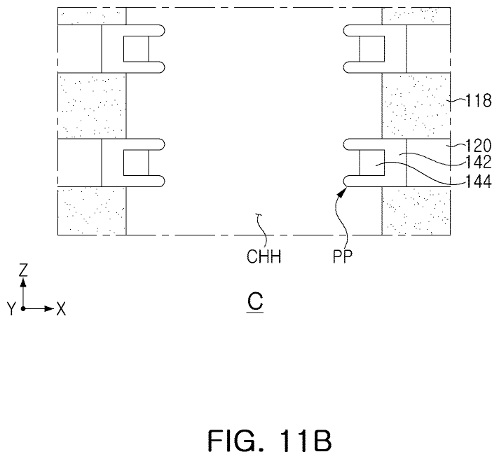

The first and second insulating layers 142 and 144 may be between the interlayer insulating layers 120 and the channel structures CH. The second insulating layers 144 may be configured to provide an oxygen diffusion path when the first insulating layers 142 are formed by an oxidation process, which will be described in greater detail with reference to FIGS. 11A and 11B below. The first and second insulating layers 142 and 144 may be at substantially the same levels as levels of the interlayer insulating layers 120. Upper surfaces of the first insulating layers 142 may be coplanar with upper surfaces of the interlayer insulating layers 120, and lower surfaces of the first insulating layers 142 may be coplanar with lower surfaces of the interlayer insulating layers 120. Each of the first and second insulating layers 142 and 144 may include a portion thereof that extends toward the channel structures CH with respect to side surfaces of the gate electrodes 130.

As illustrated in FIG. 3A, the first insulating layer 142 may fill a region where the interlayer insulating layer 120 is horizontally recessed to an external side of the channel structure CH, may extend through the channel hole in which the channel structure CH is disposed, and may contact the first dielectric layer 151. The first insulating layer 142 may contact the interlayer insulating layer 120, the gate dielectric layers 135, the first dielectric layer 151, and the second insulating layer 144. The first insulating layer 142 may cover or overlap an upper surface, a lower surface, and a side surface opposing the interlayer insulating layer 120 of the second insulating layer 144 and may surround a portion of the second insulating layer 144.

The first insulating layer 142 may include protrusion portions PP extending toward the channel structure CH such that it has a nonlinear shape for example. The protrusion portions PP may be on the upper and lower surfaces of the second insulating layer 144, respectively, and may extend from a side surface opposing the channel structure CH of the second insulating layer 144 by a first length L1. The first insulating layer 142 may overlap the gate dielectric layer 135 in the Z-direction by a second length L2, and the protrusion portions PP of the first insulating layer 142 may extend by a third length L3 from a side surface opposing the channel structure CH of the gate dielectric layer 135. The third length L3 may be greater than the second length L2. For example, the third length L3 may range from about 2.0 times to about 2.5 times the second length L2, but an example embodiment thereof is not limited thereto. As illustrated in FIG. 3B, the first insulating layer 142 may include a first lower insulating layer 142L1 and a first upper insulating layer 142L2 having a relatively long length in the Z-direction on a lower end of the channel structure CH.

The second insulating layer 144 may be completely surrounded by the first insulating layer 142 and the first dielectric layer 151. An external side surface of the second insulating layer 144, that is, a side surface that contacts the first insulating layer 142, may be on or adjacent to a conceptual line extending in the Z-direction along a side surface of the gate dielectric layer 135, but an example embodiment thereof is not limited thereto. In some example embodiments, the external side surface of the second insulating layer 144 may be shifted in various manners in the X-direction from the position illustrated in FIG. 3A.

The first and second insulating layers 142 and 144 may include an insulating material, and may include, for example, at least one of silicon oxide, silicon nitride, and silicon oxynitride. For example, the first insulating layer 142 may be formed of silicon oxide having a concentration of hydrogen (H) less than that of the interlayer insulating layer 120 and a concentration of carbon (C) less than that of the second insulating layer 144. For example, the second insulating layer 144 may be silicon oxide including carbon (C) as impurities. A concentration of carbon (C) of the second insulating layer 144 may be greater than a concentration of carbon (C) of the first insulating layer 142 and a concentration of carbon (C) of the first dielectric layer 151. In example embodiments, the interlayer insulating layer 120, the first and second insulating layers 142 and 144, and the first dielectric layer 151 may include the same material, and in this case, the interfacial surfaces may not be distinct on an image obtained by an electron microscope. However, even in this case, since concentrations of impurities of the interlayer insulating layer 120 and the first insulating layer 142 are different, concentrations of impurities of the first insulating layer 142 and the second insulating layer 144 are different, and concentrations of impurities of the second insulating layer 144 and the first dielectric layer 151 are different, the layers may be distinct from each other by component analysis.

The channel structures CH may form a memory cell string, and may be spaced apart from each other while forming rows and columns on the plate layer 101. The channel structures CH may form a lattice pattern or a zigzag pattern in one direction. The channel structures CH may have a columnar shape. The channel structures CH may have an inclined side surface such that a width thereof may decrease toward the plate layer 101 depending on an aspect ratio. In the X-direction, the channel structures CH on a linear line between the gate isolation region MS and the upper isolation region US may be connected to different bit lines 180, respectively. In some example embodiments, in a stack structure of the gate electrodes 130, a plurality of the gate electrodes 130 may be vertically stacked, and in this case, in each of the channel structures CH, a plurality of channel portions may be connected to each other.

Each of the channel structures CH may include a first dielectric layer 151, charge storage layers 152, a second dielectric layer 153, a channel layer 154, and a channel filling layer 155 sequentially stacked from an external side, and a channel pad 159. In the views, the relative thicknesses of the first dielectric layer 151, the charge storage layers 152, the second dielectric layer 153, the channel layer 154, and the channel filling layer 155 are merely examples and an example embodiment thereof is not limited thereto.

As illustrated in FIG. 3A, the first dielectric layer 151 may be between the gate dielectric layer 135 and the charge storage layers 152. The first dielectric layer 151 may overlap or cover the gate dielectric layer 135 and the first and second insulating layers 142 and 144 and may extend vertically with a curvature conforming to the shape of the first and second insulating layers 142 and 144. The first dielectric layer 151 may be connected between a pair of gate electrodes 130 that are vertically adjacent to each other and may be a single layer in the channel structure CH.

The first dielectric layer 151 may have convex portions corresponding to the protrusion portions PP of the first insulating layers 142. For example, an internal side surface of the first dielectric layer 151, that is, a side surface opposing the channel layer 154 may have first convex portions CP1. In example embodiments, with respect to the components included in the channel structure CH, the terms “external side surface” and “internal side surface” may be denoted with respect to a central axis of the channel structure CH. Two first convex portions CP1 may correspond to each of the first insulating layers 142, and the two first convex portions CP1 may have a vertically symmetrical shape. Since the first convex portions CP1 corresponds to the protrusion portions PP of the first insulating layers 142, vertices, which are the points that extend furthest from the first convex portions CP1 in the X-direction, may be at levels that are different from those of the gate electrodes 130. The vertices of the first convex portions CP1 may be at levels between adjacent gate electrodes 130. The vertices of first convex portions CP1 may be at levels corresponding to the interlayer insulating layers 120. For example, the vertices of first convex portions CP1 may be at levels adjacent to upper ends and lower ends of interlayer insulating layers 120, respectively. For example, the vertices of first convex portions CP1 may be at levels lower than levels of upper ends of the interlayer insulating layers 120 and higher than levels of lower ends, respectively.

The charge storage layers 152 may be between the first dielectric layer 151 and the second dielectric layer 153, may be isolated from each other between a pair of gate electrodes 130 that are vertically adjacent to each other, and may be in a plurality of layers in a channel structure CH. A length L5 of an internal side surface of each of the charge storage layers 152, that is, a side surface opposing the channel layer 154, may be greater than a length L4 of an external side surface, that is, a side surface opposing the gate electrode 130. The length of each of the charge storage layers 152 in the Z-direction may be equal to or greater than a sum of the length of gate electrode 130 and the thickness of gate dielectric layers 135 on the upper and lower surfaces of gate electrode 130, which may be a value obtained by subtracting twice the thickness of the first dielectric layer 151 from the sum of the length of the gate electrode 130 and twice the thickness of the gate dielectric layers 135, which may be due to a process of manufacturing the semiconductor device 100.

The second dielectric layer 153 may extend vertically while covering/overlapping internal side surfaces of the charge storage layers 152 and a portion of the first dielectric layer 151. The second dielectric layer 153 may have a curvature along the charge storage layers 152 and the first dielectric layer 151. The second dielectric layer 153 may be connected between a pair of gate electrodes 130 that are vertically adjacent to each other and may be a single layer in the channel structure CH. The second dielectric layer 153 may have convex portions corresponding to the first convex portions CP1 of the first dielectric layer 151, and for example, an internal side surface may have the second convex portions CP2. Levels of vertices of the second convex portions CP2 may be at the same levels of vertices of the protrusion portions PP of the first insulating layers 142 and the same levels of vertices of the first convex portions CP1, or the levels of vertices of the second convex portions CP2 may be at substantially the same levels as the above levels. An external side surface of the second dielectric layer 153 may have inwardly curved portions in contact with the first convex portions CP1.

The channel layer 154 may have an annular shape at least partially surrounding the channel filling layer 150 on the internal side. However, in some example embodiments, when the channel filling layer 150 is not provided, the channel layer 154 may have a columnar shape such as a cylindrical shape or a prism shape. The channel layer 154 may cover or overlap an internal side surface of the second dielectric layer 153 and may extend vertically. The channel layer 154 may have a curvature along the second dielectric layer 153. As illustrated in FIG. 3B, the channel layer 154 may be connected to the first horizontal conductive layer 102 in a lower portion. The channel layer 154 may have convex portions corresponding to the second convex portions CP2 of the second dielectric layer 153, and for example, an internal side surface may have third convex portions CP3. A level of vertices of the third convex portions CP3 may be at the same levels of vertices of the protrusion portions PP of the first insulating layers 142 and at the same levels of vertices of the first and second convex portions CP1 and CP2, or may be substantially at the same levels as the above levels. An external side surface of the channel layer 154 may have inwardly curved portions that contact the second convex portions CP2.

Vertices of protrusion portions PP of the first insulating layers 142 and vertices of first to third convex portions CP1, CP2, and CP3 may be at levels between a pair of gate electrodes 130 that are vertically adjacent to each other. That is, the vertices of first to third convex portions CP1, CP2, and CP3 may not overlap the gate electrodes 130 in the horizontal direction. Also, the first to third convex portions CP1, CP2, and CP3 may be described as inwardly curved portions of layers that contact the first to third convex portions CP1, CP2, and CP3.

The channel filling layer 155 may fill a channel hole in which the channel structure CH is on an internal side of the channel layer 154. A side surface of the channel filling layer 155 may contact the third convex portions CP3 of the channel layer 154 and may have inwardly curved portions or concave portions corresponding to the shape of the third convex portions CP3. The channel filling layer 155 may have first widths W1, which are minimum widths, on levels of the inwardly curved portions, that is, levels of vertices of third convex portions CP3 of the channel layer 154. The channel fill layer 155 may have two points having a first width W1 which is a minimum width in a region opposing a single interlayer insulating layer 120. The channel filling layer 155 may have a second width W2 greater than the first width W1 at a level between the third convex portions CP3 that are vertically adjacent to each other. The channel filling layer 155 may have a third width W3 greater than a first width W1 and a second width W2 on a level corresponding to a portion of the gate electrodes 130. Points at which the channel filling layer 155 has the first widths W1 and the inwardly curved portions may be at levels adjacent to upper ends and lower ends of the interlayer insulating layers 120, for example, at levels corresponding to levels of the interlayer insulating layers 120.

The channel pad 159 may be on an upper end of the channel structure CH, and the channel pad 159 may fill an internal side of the channel layer 154 in a region in which the channel filling layer 155 is partially recessed. The channel pad 159 may cover an upper surface of the channel filling layer 155 and may be electrically connected to the channel layer 154.

Each of the first dielectric layer 151 and the second dielectric layer 153 may include silicon oxide (SiO₂) silicon nitride (Si₃N₄), silicon oxynitride (SiON), a high-K dielectric material, or a combination thereof. The first dielectric layer 151 may include a material different from that of the gate dielectric layer 135, and may include a material different from that of the second dielectric layer 153, but an example embodiment thereof is not limited thereto. The first dielectric layer 151 may include, for example, silicon oxide (SiO₂), the second dielectric layer 153 may include silicon oxynitride (SiON), and the gate dielectric layer 135 may include aluminum oxide (Al₂O₃). The charge storage layers 152 may be a charge trap layer or a floating gate conductive layer, and when the charge storage layers 152 is a charge trap layer, the charge storage layers 152 may be formed of silicon nitride. The channel layer 154 may include a semiconductor material such as polycrystalline silicon or single crystal silicon, and the semiconductor material may be an undoped material, or a material including P-type or N-type impurities. The channel pad 159 may include a conductive material, for example, doped polycrystalline silicon.

The gate isolation regions MS may extend through a portion of the gate electrodes 130 and may extend in the Y-direction. As illustrated in FIG. 1, the gate isolation regions MS may be parallel to each other. The gate isolation regions MS may be connected to the plate layer 101 by extending through the gate electrodes 130 on the plate layer 101 and further extending through the first and second horizontal conductive layers 102 and 104 therebelow.

A gate isolation insulating layer 105 may be in each of the gate isolation regions MS. The gate isolation insulating layer 105 may have a shape in which a width thereof may decrease toward the plate layer 101 due to a high aspect ratio. The gate isolation insulating layer 105 may include an insulating material, for example, silicon oxide, silicon nitride, or silicon oxynitride.

As illustrated in FIG. 1, the upper isolation region US may extend in the Y-direction between adjacent gate isolation regions MS. The upper isolation region US may extend through a portion of the gate electrodes 130 including the uppermost upper gate electrode 130U among the gate electrodes 130. As illustrated in FIG. 2, the upper isolation region US may isolate, for example, three gate electrodes 130 from each other in the X-direction. However, the number of gate electrodes 130 isolated from each other by the upper isolation region US may vary in other embodiments.

Each of the upper isolation regions US may include an upper isolation insulating layer 103. The upper isolation insulating layer 103 may include an insulating material, for example, silicon oxide, silicon nitride, or silicon oxynitride.

The studs 170 and bit lines 180 may form a cell interconnection structure electrically connected to memory cells. The studs 170 may be connected to the channel pads 159 and may be electrically connected to the channel structures CH. Studs 170 may electrically connect the channel structures CH to bit lines 180 on an upper portion. The studs 170 may have a plug shape in the illustrated example, but an example embodiment thereof is not limited thereto, and the studs may have a linear shape. In example embodiments, the number of the plugs and the interconnection lines included in the cell interconnection structure may be varied. The bit lines 180 may extend in the X-direction. As illustrated in FIG. 2, the bit lines 180 may be electrically connected to one channel structure CH through the studs 170 between the gate isolation region MS and the upper isolation region US that are adjacent to each other. The studs 170 and the bit lines 180 may include metal, for example, tungsten (W), copper (Cu), or aluminum (Al).

The cell region insulating layer 190 may overlap or cover a stack structure of the gate electrodes 130, the studs 170, and the bit lines 180. The cell region insulating layer 190 may be formed of an insulating material or may include a plurality of insulating layers.

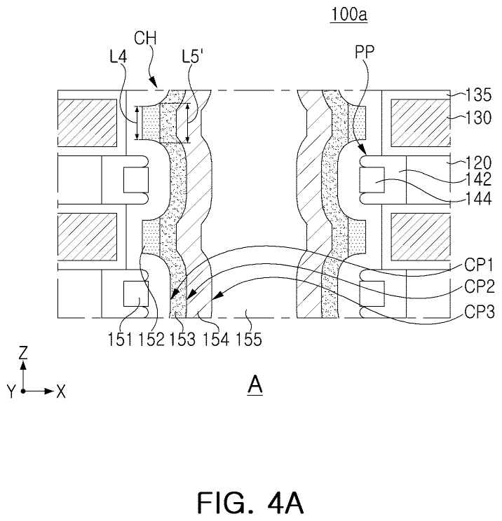

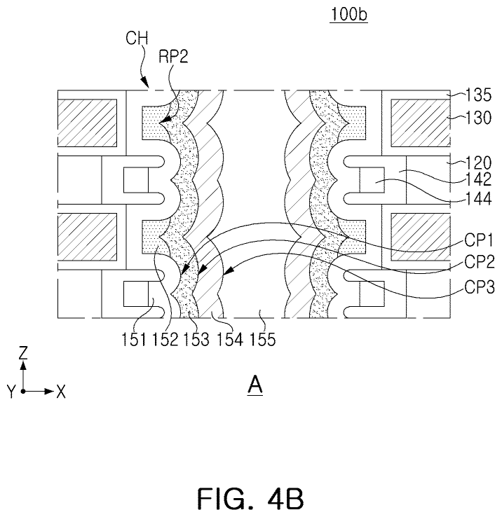

FIGS. 4A and 4B are enlarged views illustrating a semiconductor device according to an example embodiment illustrating regions corresponding to FIG. 3A.

Referring to FIG. 4A, in the semiconductor device 100a, extension lengths of protrusion portions PP of the first insulating layers 142 may be different than the example embodiment in FIG. 3A. The protrusion portions PP may not extend from a side surface opposing the channel layer 154 of the second insulating layers 144, and ends thereof may be on upper surfaces and lower surfaces of the second insulating layers 144. Accordingly, the first to third convex portions CP1, CP2, and CP3 may be integrated with each other in regions opposing one interlayer insulating layer 120, instead of being in two portions as in the example embodiment in FIG. 3A. Vertices of the first to third convex portions CP1, CP2, and CP3 may be at a same level as a level of a center of each of the interlayer insulating layers 120 in the Z-direction. In some example embodiments, depending on the extension length of the protrusion portions PP, the first to third convex portions CP1, CP2, and CP3 may have a shape in which the degree of curvature may be relatively reduced as compared to the example embodiment in FIG. 3A.

The charge storage layers 152 may have a relatively vertically extended length, and for example, a difference between a length L4 of the external side surface and a length L5′ of the internal side surface may be relatively large. Even in this case, the length L5′ of the internal side surface may be less than the length of the gate electrode 130, but an example embodiment thereof is not limited thereto.

Referring to FIG. 4B, in the semiconductor device 100b, the charge storage layers 152 may have recess portions RP2 on an internal side surface. In the charge storage layer 152, the recess portion RP2 may be formed on an internal side surface that contacts the second dielectric layer 153 and may have a shape recessed toward a center in the Z-direction. Accordingly, the charge storage layer 152 may have a minimum width in the X-direction in the central region in the Z-direction, and may have a shape in which a width thereof may increase toward an upper end and a lower end. The second dielectric layer 153 and the channel layer 154 may also have recess regions corresponding to the recess portions RP2 on internal side surfaces thereof.

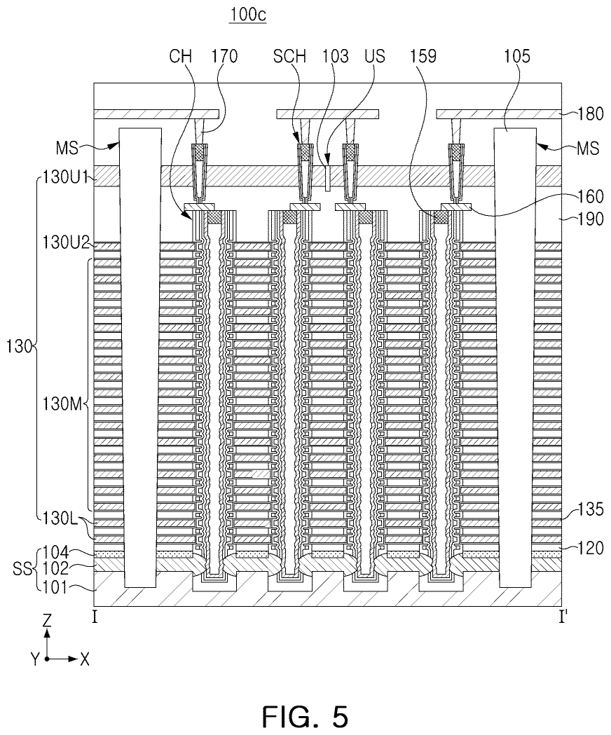

FIG. 5 is a cross-sectional view illustrating a semiconductor device according to an example embodiment illustrating a region corresponding to FIG. 2.

Referring to FIG. 5, a semiconductor device 100c may further include string channel structures SCH connected to channel structures CH.

Among the gate electrodes 130, the upper gate electrodes 130U may include a first upper gate electrode 130U1 of an uppermost portion and a second upper gate electrode 130U2 below the first upper gate electrode 130U1. The first upper gate electrode 130U1 may be spaced apart from the second upper gate electrode 130U2 by a relatively large distance compared to the distance between other gate electrodes 130, and may have a relatively larger thickness compared to the thickness of other gate electrodes 130. The string channel structures SCH may extend through the first upper gate electrode 130U1, and the channel structures CH may extend through the gate electrodes 130 except for the first upper gate electrode 130U1. The first upper gate electrode 130U1 may include a material that is the same as or different from that of the other gate electrodes 130. For example, the first upper gate electrode 130U1 may include polycrystalline silicon, and the gate electrodes 130 other than the first upper gate electrode 130U1 may include a metal material. The gate dielectric layer 135 may not be on a surface of the first upper gate electrode 130U1.

String channel structures SCH may be connected to the channel structures CH, respectively. The string channel structures SCH may be on the channel structures CH, respectively, and may be shifted from the channel structures CH in the horizontal direction, but an example embodiment thereof is not limited thereto. Similarly to the channel structures CH, the string channel structures SCH may include at least one string dielectric layer, a string channel layer, and a string channel filling layer stacked sequentially from the first upper gate electrode 130U1 in the string channel hole, and may further include a string channel pad on an upper end and a connection pad 160 that is below the string channel hole. The string channel layer may be connected to the connection pad 160 in a lower portion, and may be electrically connected to the channel layer 154 (see FIG. 3A) of the channel structure CH through the connection pad 160.

As for the materials of the string channel layer, the string dielectric layer, the string channel filling layer, and the string channel pad, the descriptions of the channel layer 154, the first and second dielectric layers 151 and 153, the channel filling layer 155, and the channel pad 159 may be applied, respectively. The connection pad 160 may include a conductive material, for example polycrystalline silicon.

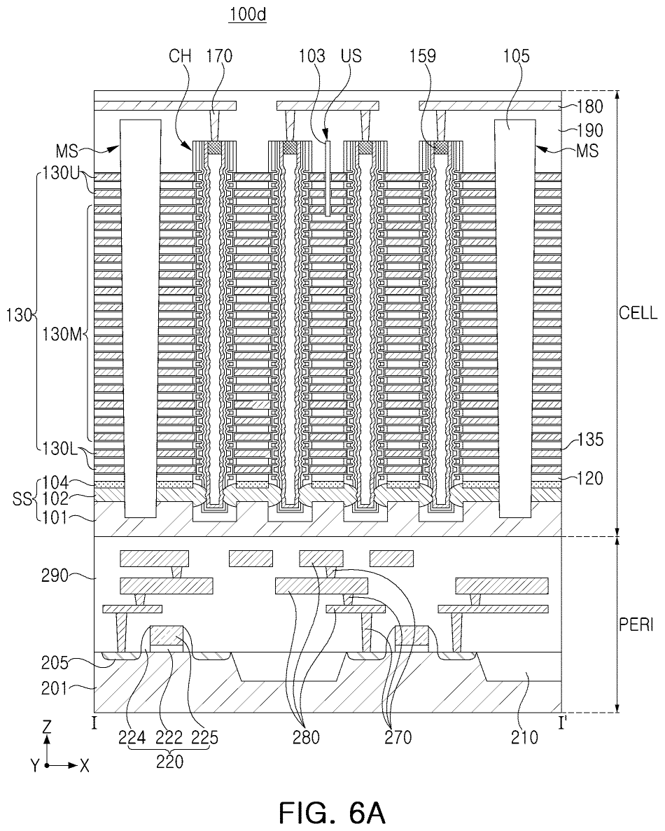

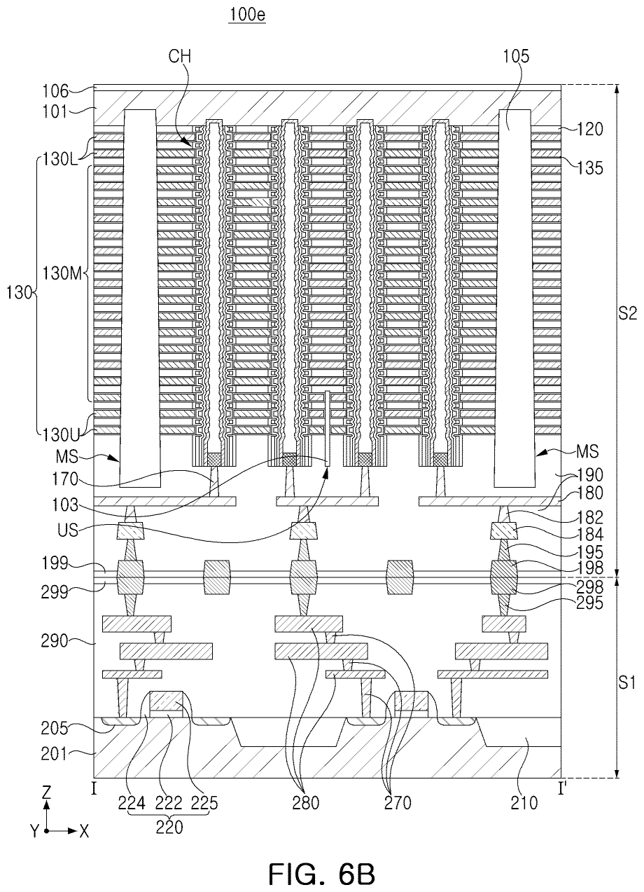

FIGS. 6A and 6B are cross-sectional views illustrating a semiconductor device according to an example embodiment illustrating a region corresponding to FIG. 2.

Referring to FIG. 6A, a semiconductor device 100d may include a memory cell region CELL and a peripheral circuit region PERI that may be vertically stacked. The memory cell region CELL may be on the peripheral circuit region PERI. For example, in the case of the semiconductor device 100 in FIG. 2, a peripheral circuit region PERI may be on the plate layer 101 (not illustrated), and in the semiconductor device 100d of the example embodiment, the memory cell region CELL and the peripheral circuit region PERI may be vertically stacked. In example embodiments, the cell region CELL may be below the peripheral circuit region PERI. The description with reference to FIGS. 1 to 3B may be applied to the description of the memory cell region CELL.

The peripheral circuit region PERI may include a substrate 201, impurity regions 205 and device isolation layers 210 in the substrate 201, circuit devices 220 on substrate 201, a peripheral region insulating layer 290, circuit contact plugs 270, and circuit interconnection lines 280.

The substrate 201 may have an upper surface extending in the X-direction and the Y-direction. In the substrate 201, an active region may be defined by the device isolation layers 210. The impurity regions 205 including impurities may be in a portion of the active region. The substrate 201 may include a semiconductor material, such as a group IV semiconductor, a group III-V compound semiconductor, or a group II-VI compound semiconductor. The substrate 201 may be a bulk wafer or epitaxial layer.

The circuit devices 220 may include planar transistors. Each of the circuit devices 220 may include a circuit gate dielectric layer 222, a spacer layer 224 and a circuit gate electrode 225. The impurity regions 205 may be source/drain regions in the substrate 201 on both sides of the circuit gate electrode 225.

The peripheral region insulating layer 290 may be on the circuit device 220 on the substrate 201. The peripheral region insulating layer 290 may include a plurality of insulating layers formed in different processes. The peripheral region insulating layer 290 may be formed of an insulating material.

The circuit contact plugs 270 and circuit interconnection lines 280 may form a circuit interconnection structure electrically connected to the circuit devices 220 and the impurity regions 205. The circuit contact plugs 270 may have a cylindrical shape, and the circuit interconnection lines 280 may have a linear shape. An electrical signal may be applied to the circuit device 220 by the circuit contact plugs 270 and the circuit interconnection lines 280. In a region not illustrated, the circuit contact plugs 270 may also be connected to the circuit gate electrode 225. The circuit interconnection lines 280 may be connected to the circuit contact plugs 270, may have a linear shape, and may have a plurality of layers. The circuit contact plugs 270 and the circuit interconnection lines 280 may include a conductive material, for example, tungsten (W), copper (Cu), aluminum (Al), and the like, and each component may further include a diffusion barrier. In example embodiments, the number of layers of the circuit contact plugs 270 and the circuit interconnection lines 280 may be varied.

As described above, the form in which the memory cell region CELL and the peripheral circuit region PERI are vertically stacked may be applied to other example embodiments described herein.

Referring to FIG. 6B, a semiconductor device 100e may include a first semiconductor structure S1 and a second semiconductor structure S2 bonded to each other by a wafer bonding method.

The description of the peripheral circuit region PERI described above with reference to FIG. 6A may be applied to the first semiconductor structure S1. However, first semiconductor structure S1 may further include first bonding vias 295, first bonding metal layers 298, and a first bonding insulating layer 299, which are bonding structures. The first bonding vias 295 may be in an upper portion of the uppermost circuit interconnection lines 280 and may be connected to the circuit interconnection lines 280. At least a portion of the first bonding metal layers 298 may be connected to the first bonding vias 295 on the first bonding vias 295. The first bonding metal layers 298 may be connected to the second bonding metal layers 198 of the second semiconductor structure S2. The bonding metal layers 298 may provide an electrical connection path based on the bonding between the first semiconductor structure S1 and the second semiconductor structure S2 together with the second bonding metal layers 198. A portion of the first bonding metal layers 298 may be disposed only for bonding without being connected to the circuit interconnection lines 280 of the lower portion. The first bonding vias 295 and the first bonding metal layers 298 may include a conductive material such as copper (Cu). A first bonding insulating layer 299 may surround the first bonding metal layers 298. The first bonding insulating layer 299 may also function as a diffusion barrier of the first bonding metal layers 298, and may include, for example, at least one of SiN, SiON, SiCN, SiOC, SiOCN, and SiO.

As for the second semiconductor structure S2, the description described above with reference to FIGS. 1 to 3B may be applied unless otherwise indicated. The second semiconductor structure S2 may further include cell contact plugs 182 and cell interconnection lines 184, which are cell interconnection structures, and may further include second bonding vias 195, second bonding metal layers 198, and second bonding insulating layer 199, which are bonding structures. The second semiconductor structure S2 may further include a passivation layer 106 covering or overlapping an upper surface of the plate layer 101.

The cell contact plugs 182 may be connected to the bit lines 180, and the cell interconnection lines 184 may be connected to the cell contact plugs 182. However, in example embodiments, the number of layers of the contact plugs and the interconnection lines included in the cell interconnection structure and the arrangement form thereof may be varied. The cell contact plugs 182 and the cell interconnection lines 184 may be formed of a conductive material, and may include, for example, at least one of tungsten (W), aluminum (Al), and copper (Cu).

The second bonding vias 195 and the second bonding metal layers 198 may be below the cell interconnection lines 184 in the lowermost portion. The second bonding vias 195 may connect the cell interconnection lines 184 to the second bonding metal layers 198, and the second bonding metal layers 198 may be bonded to the first bonding metal layers 298 of the first semiconductor structure S1. The second bonding insulating layer 199 may be bonded and connected to the first bonding insulating layer 299 of the first semiconductor structure S1. The second bonding vias 195 and the second bonding metal layers 198 may include a conductive material such as copper (Cu). The second bonding insulating layer 199 may include, for example, at least one of SiO, SiN, SiCN, SiOC, SiON, and SiOCN.

The first and second semiconductor structures S1 and S2 may be bonded to each other by bonding between the first bonding metal layers 298 and the second bonding metal layers 198 and bonding between the first bonding insulating layer 299 and the second bonding insulating layer 199. The bonding between the first bonding metal layers 298 and the second bonding metal layers 198 may be, for example, copper (Cu)-to-copper (Cu) bonding, and the bonding between the first bonding insulating layer 299 and the second bonding insulating layer 199 may be, for example, dielectric-to-dielectric bonding such as SiCN-to-SiCN bonding. The first and second semiconductor structures S1 and S2 may be bonded to each other by hybrid bonding including copper (Cu)-to-copper (Cu) bonding and dielectric-to-dielectric bonding.

The passivation layer 106 may be on the upper surface of the plate layer 101 and may protect the semiconductor device 100e. The passivation layer 106 may include an insulating material, for example, at least one of silicon oxide, silicon nitride, and silicon carbide, and may include a plurality of insulating layers according to example embodiments.

In the example embodiment, the semiconductor device 100e may not include the first and second horizontal conductive layers 102 and 104, and the channel layers 154 of the channel structures CH may be directly connected to the plate layer 101 through an upper end. However, in some example embodiments, the semiconductor device 100e may include the first and second horizontal conductive layers 102 and 104 and may have a shape corresponding to FIG. 2.

As described above, the form in which the first semiconductor structure S1 and the second semiconductor structure S2 are vertically bonded to each other may also be applied to other example embodiments.

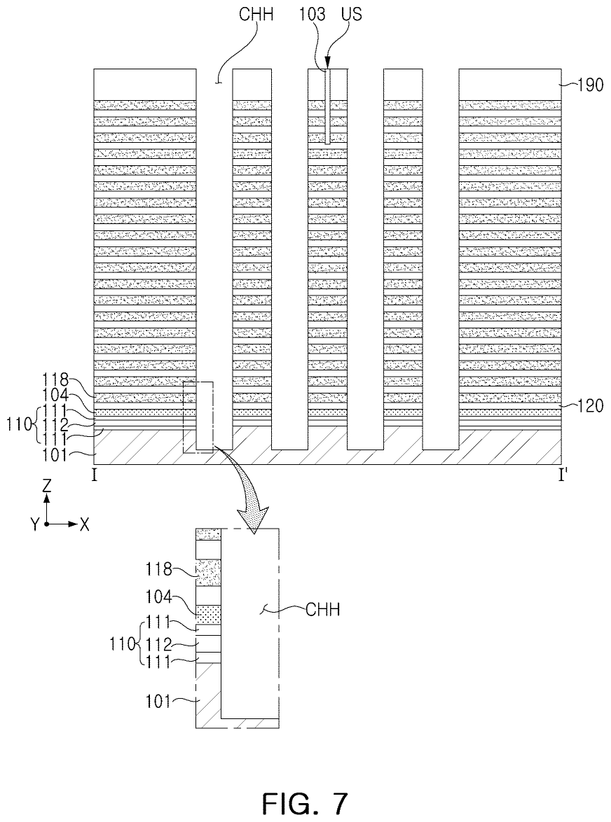

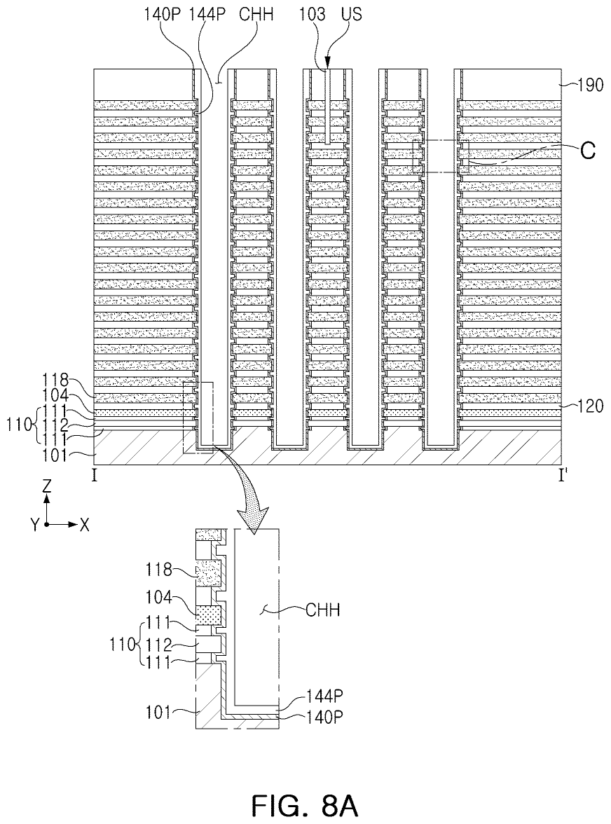

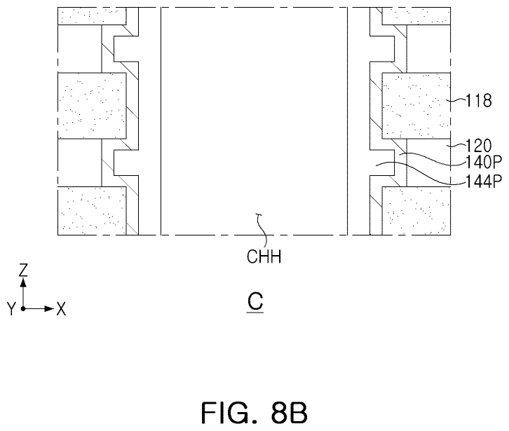

FIGS. 7, 8A, 9A, 10A, 11A, 12A, 13A, 14, 15, and 16 are cross-sectional views a method of manufacturing a semiconductor device according to an example embodiment illustrating a region corresponding to FIG. 2. FIGS. 8B, 9B, 10B, 11B, 12B, and 13B are cross-sectional views a method of manufacturing a semiconductor device according to an example embodiment illustrating region “C” in FIGS. 8A, 9A, 10A, 11A, 12A, and 13A, respectively.

Referring to FIG. 7, a horizontal insulating layer 110 and a second horizontal conductive layer 104 may be formed on a plate layer 101, a mold structure may be formed by alternately stacking the sacrificial insulating layers 118 and the interlayer insulating layers 120, an upper isolation region US may be formed, and channel holes CHH extending through the mold structure may be formed.

The first and second horizontal insulating layers 111 and 112 included in the horizontal insulating layer 110 may be alternately stacked on the plate layer 101. The horizontal insulating layer 110 may be replaced with the first horizontal conductive layer 102 in FIG. 2 through a subsequent process. The first horizontal insulating layers 111 may include a material different from that of the second horizontal insulating layer 112. For example, the first horizontal insulating layers 111 may be formed of the same material as that of the interlayer insulating layers 120, and the second horizontal insulating layer 112 may be formed of the same material as that of the sacrificial insulating layers 118. A second horizontal conductive layer 104 may be formed on the horizontal insulating layer 110.

The sacrificial insulating layers 118 forming the mold structure may be replaced with gate electrodes 130 (see FIG. 2) and gate dielectric layers 135 (see FIG. 2) through a subsequent process. The sacrificial insulating layers 118 may be formed of a material different from that of the interlayer insulating layers 120, and may be formed of a material etched with etch selectivity under specific etching conditions with respect to the interlayer insulating layers 120. For example, the interlayer insulating layer 120 may be formed of at least one of silicon oxide and silicon nitride, and the sacrificial insulating layers 118 may be formed of a material different from that of the interlayer insulating layer 120 selected from among silicon, silicon oxide, silicon carbide, and silicon nitride. In example embodiments, the interlayer insulating layers 120 may not have the same thickness. The thickness of the interlayer insulating layers 120 and the sacrificial insulating layers 118 and the number of layers thereof may be varied from the illustrated example. A cell region insulating layer 190 may be formed on the mold structure.

The upper isolation region US may be formed by forming an opening by removing a portion of the mold structure and depositing upper isolation insulating layers 103 in the opening. In some example embodiments, the upper isolation region US may be formed in a subsequent process, for example, may be formed after the channel structures CH are formed.

The channel holes CHH may be formed by anisotropically etching the sacrificial insulating layers 118 and the interlayer insulating layers 120, and may be formed in a hole shape. Due to the level of the mold structure, a sidewall of the channel holes CHH may not be perpendicular to an upper surface of the plate layer 101. The channel holes CHH may be formed to be recessed into a portion of the plate layer 101.

Referring to FIGS. 8A and 8B, the interlayer insulating layers 120 may be partially recessed, and a preliminary oxide formation layer 140P and a preliminary second insulating layer 144P may be formed.

The interlayer insulating layers 120 may be removed to a predetermined depth from a side surface exposed through the channel holes CHH. During the process of recessing the interlayer insulating layers 120, the first horizontal insulating layers 111 may also be recessed in a lower portion of the channel holes CHH.

The preliminary oxide formation layer 140P may be formed to cover or overlap a sidewall and a bottom surface of the channel holes CHH. The preliminary oxide formation layer 140P may be conformally formed covering or overlapping the recessed side surfaces of the interlayer insulating layers 120. The preliminary oxide formation layer 140P may have recess regions corresponding to recess regions of the interlayer insulating layers 120. The preliminary oxide formation layer 140P may be oxidized in a subsequent process and may form the first insulating layers 142 (see FIG. 3A). The preliminary oxide formation layer 140P may be, for example, a semiconductor layer such as polycrystalline silicon. In some example embodiments, the preliminary oxide formation layer 140P may include a metal material.

The preliminary second insulating layer 144P may be formed on the preliminary oxide formation layer 140P. The preliminary second insulating layer 144P may be formed to fill recess regions of the preliminary oxide formation layer 140P. The preliminary second insulating layer 144P may be deposited at a low temperature, for example, room temperature, and may include carbon (C) impurities therein. The preliminary second insulating layer 144P may form second insulating layers 144 (see FIG. 3A) through a subsequent process.

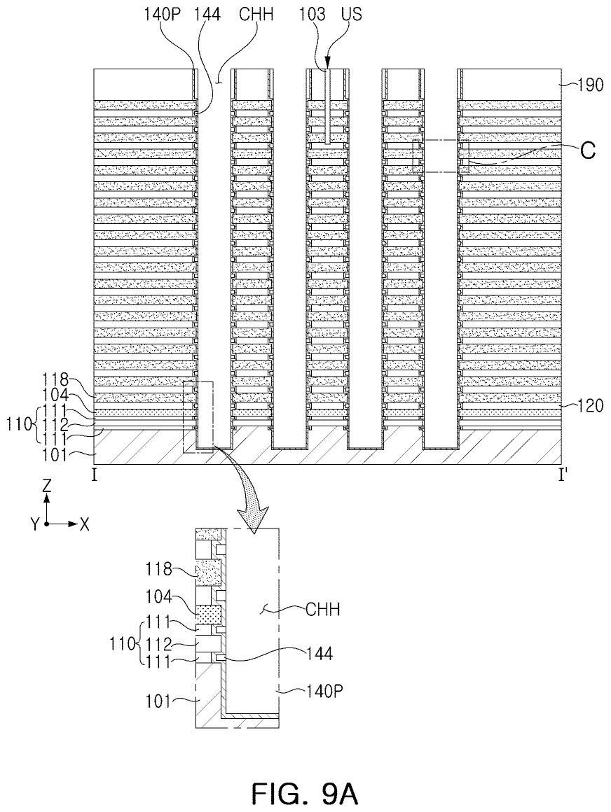

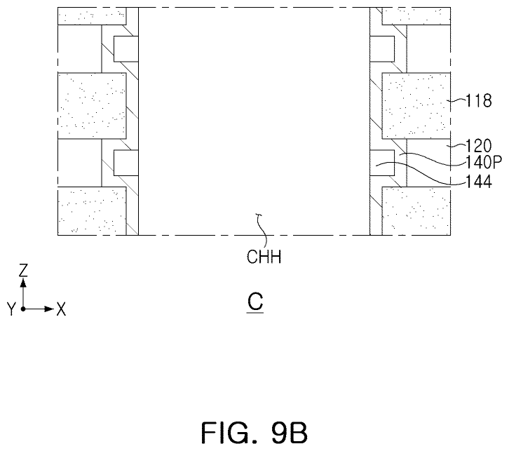

Referring to FIGS. 9A and 9B, second insulating layers 144 may be formed by partially removing the preliminary second insulating layer 144P.

In the preliminary second insulating layer 144P, only regions filling recess regions of the oxide formation layer 140 may remain by, for example, a trimming process, to thereby form the second insulating layers 144.

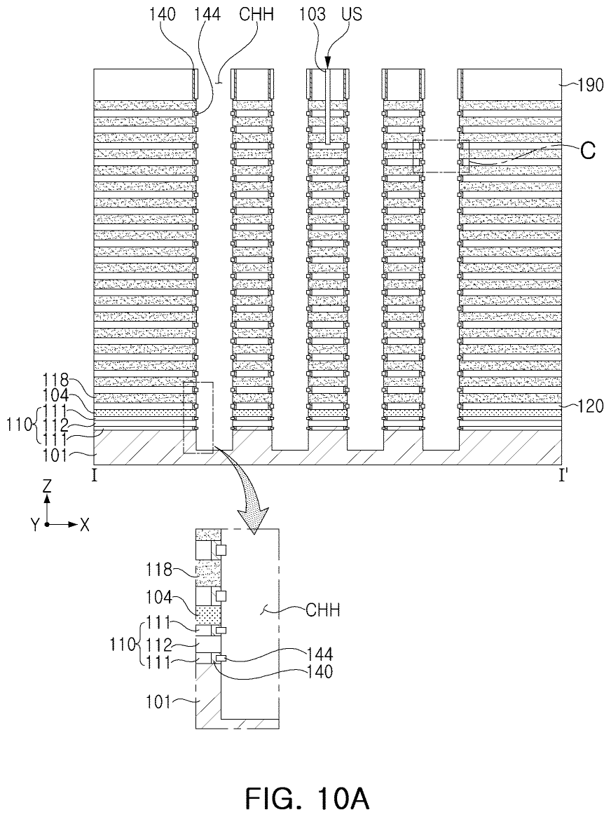

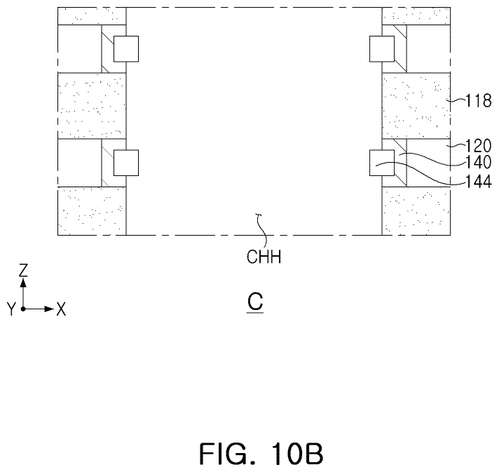

Referring to FIGS. 10A and 10B, oxide formation layers 140 may be formed by partially removing the preliminary oxide formation layer 140P.

In the preliminary oxide formation layer 140P, for example, only regions filling recess regions of the interlayer insulating layers 120 may remain by a trim process and may form the oxide formation layers 140. In the example embodiment, the preliminary oxide formation layer 140P may be selectively removed on the side surfaces of the sacrificial insulating layers 118 to have side surfaces coplanar with the side surfaces of the sacrificial insulating layers 118. Accordingly, the second insulating layers 144 may remain as a plurality of layers in which a portion thereof may be covered with the oxide formation layers 140 and another portion may be exposed into the channel holes CHH.

In the example embodiment in FIG. 10A, a relatively large amount of the preliminary oxide formation layer 140P may be removed in this process. Specifically, the exposed side surface of the remaining oxide formation layers 140 may be recessed further than the side surfaces of the sacrificial insulating layers 118, may be on the external side of the sacrificial insulating layers 118, and may be shifted toward the interlayer insulating layers 120.

Referring to FIGS. 11A and 11B, first insulating layers 142 may be formed by oxidizing the oxide formation layers 140.

As the process of oxidation of the oxide formation layers 140, for example, a wet oxidation process in which by supplying high-temperature oxygen (O₂) and hydrogen (H₂) gas, water vapor thereof may be formed and supplied into a process chamber, but an example embodiment thereof is not limited thereto. By the oxidation process, first insulating layers 142 of which a volume may increase in a horizontal direction may be formed from the oxide formation layers 140. For example, a length of the first insulating layer 142 in the horizontal direction may range from about 2.0 times to about 2.5 times the length of the oxide formation layer 140 in the horizontal direction. During the process of oxidation the oxide formation layers 140, the second insulating layers 144 may be used as an oxygen diffusion path. Accordingly, the oxidation process may be performed efficiently, such that the entirety of the oxide formation layers 140 may be oxidized. By forming the second insulating layers 144, the volume of the oxide formation layers 140 may be relatively reduced, such that the process time and temperature may be reduced, and the thickness of the first lower insulating layer 142L1 on a lower end of the channel hole CHH may be reduced. Volume expansion in the vertical direction may be reduced, thereby reducing distortion of the mold structure.

Each of the first insulating layers 142 may surround each of the second insulating layers 144 and may be formed in a shape of rabbit car in a Y-direction. The first insulating layers 142 may have protrusion portions PP protruding into the channel holes CHH.

In this process, the first insulating layer 142 may also be formed on the side surfaces of the first horizontal insulating layers 111 in a lower portion of the channel holes CHH. The plate layer 101 and second horizontal conductive layer 104 may also be partially oxidized, such that the first insulating layer 142 on the side surfaces of the first horizontal insulating layers 111 may extend onto exposed regions of the plate layer 101 and the second horizontal conductive layer 104, and may form the first lower insulating layer 142L1 and the first upper insulating layer 142L2. However, in example embodiments, the shapes and the relative thicknesses of the first lower insulating layer 142L1 and the first upper insulating layer 142L2 may not be limited to the example embodiment illustrated in FIG. 11A.

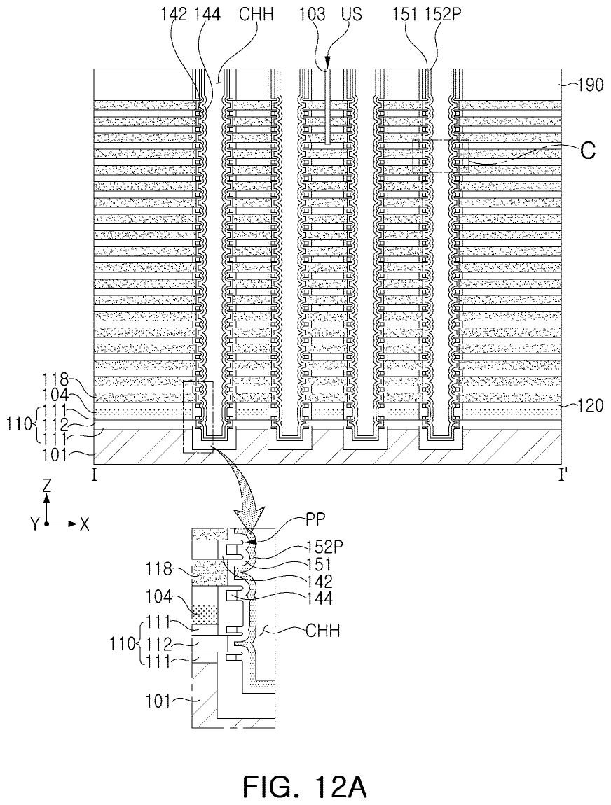

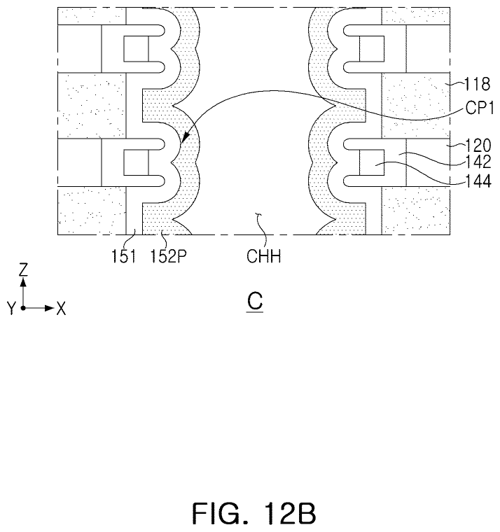

Referring to FIGS. 12A and 12B, a first dielectric layer 151 may be formed in the channel hole CHH, and a preliminary charge storage layer 152P may be formed on the first dielectric layer 151.

The first dielectric layer 151 may be conformally formed along the first and second insulating layers 142 and 144 and the sacrificial insulating layers 118. The first dielectric layer 151 may be formed to have a substantially uniform thickness. The first dielectric layer 151 may have first convex portions CP1 corresponding to the protrusion portions PP of the first insulating layers 142.

The preliminary charge storage layer 152P may be conformally formed on the first dielectric layer 151. The preliminary charge storage layer 152P may be formed to have a substantially uniform thickness. In the example embodiment in FIG. 12B, in this process, the preliminary charge storage layer 152P may be formed to have a relatively smaller thickness.

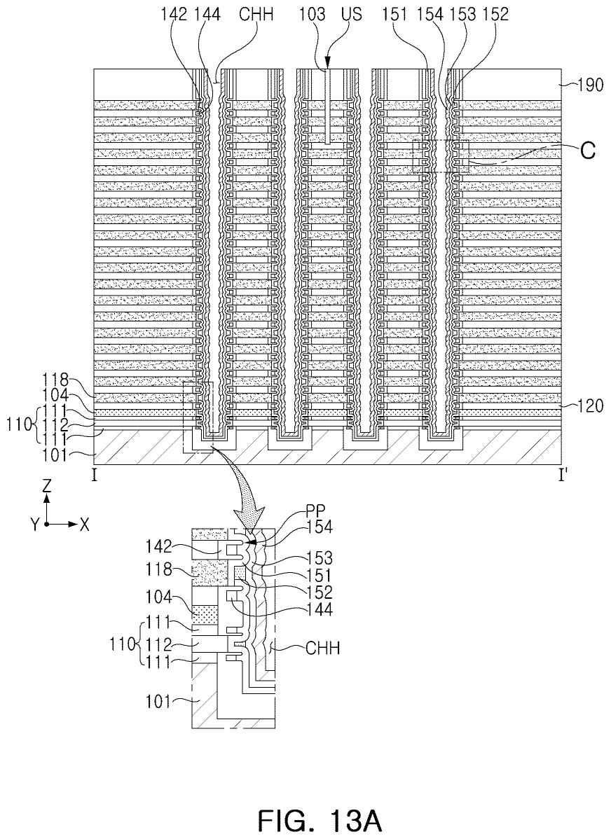

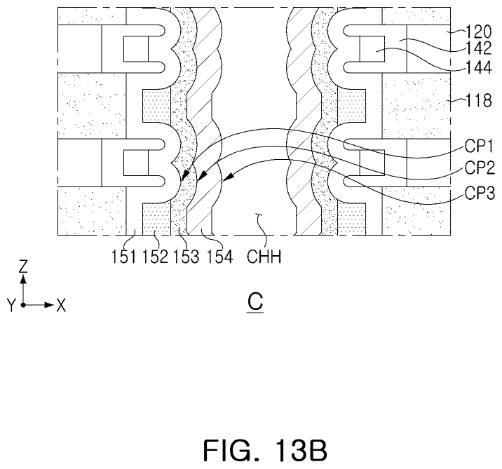

Referring to FIGS. 13A and 13B, a portion of the preliminary charge storage layers 152P may be removed to form charge storage layers 152, and a second dielectric layer 153 and a channel layer 154 may be formed.

In the preliminary charge storage layer 152P, for example, only regions filling recess regions of the first dielectric layer 151 may remain on levels corresponding to the sacrificial insulating layers 118 by a trim process and may form the charge storage layers 152.

The second dielectric layer 153 may be conformally formed to cover or overlap the charge storage layers 152 and the first dielectric layer 151. The channel layer 154 may be conformally formed on the second dielectric layer 153. Each of the second dielectric layer 153 and channel layer 154 may have a substantially uniform thickness. The second dielectric layer 153 may have second convex portions CP2 corresponding to first convex portions CP1. The channel layer 154 may have third convex portions CP3 corresponding to the second convex portions CP2.

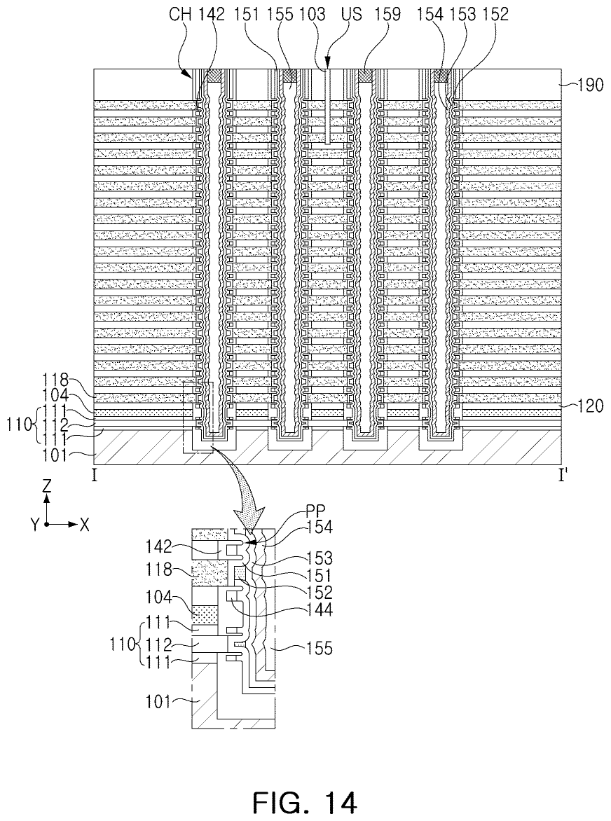

Referring to FIG. 14, channel structures CH may be formed by forming a channel filling layer 155 and a channel pad 159.

The channel filling layer 155 may be formed to fill the channel hole CHH on the channel layer 154. The channel pad 159 may be formed to be connected to the channel layer 154 after partially removing the channel filling layer 155 from an upper end of the channel hole CHH. Accordingly, the channel structures CH each including the first dielectric layer 151, the charge storage layers 152, the second dielectric layer 153, the channel layer 154, the channel filling layer 155, and the channel pad 159 may be formed.

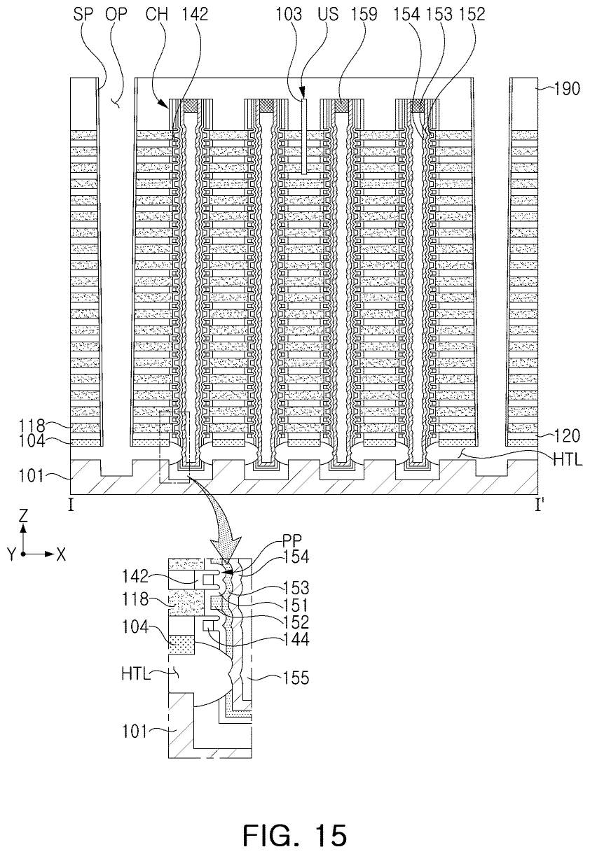

Referring to FIG. 15, in regions corresponding to the isolation regions MS (see FIG. 2), trenches OP extending through the stack structure of sacrificial insulating layers 118 and the interlayer insulating layers 120 may be formed, and the horizontal insulating layer 110 may be removed, thereby forming a horizontal tunnel portion HTL.

A cell region insulating layer 190 may be additionally formed on the channel structures CH and the trenches OP may be formed. The trenches OP may be formed to extend through the mold structure of the sacrificial insulating layers 118 and the interlayer insulating layers 120, may extend through the second horizontal conductive layer 104 in a lower portion, and may extend in the Y-direction.

Thereafter, sacrificial spacer layers SP may be formed in the trenches OP and the second horizontal insulating layer 112 may be exposed by an etchback process. A horizontal tunnel portion HTL may be formed by selectively removing the exposed second horizontal insulating layer 112 and removing the upper and lower first horizontal insulating layers 111. The horizontal insulating layer 110 may be removed by, for example, a wet etching process. During the process of removing the horizontal insulating layer 110, the exposed first lower insulating layer 142L1, the first upper insulating layer 142L2, the first dielectric layer 151 and the second dielectric layer 153 may be partially removed together, thereby forming a contact region in which an external side surface of channel layer 154 is exposed.

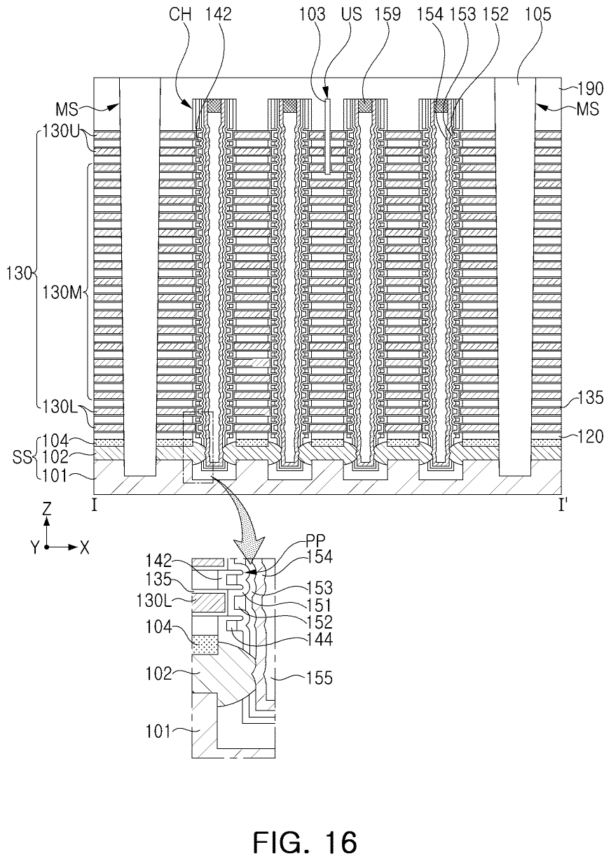

Referring to FIG. 16, the first horizontal conductive layer 102 may be formed, the sacrificial insulating layers 118 may be removed, gate dielectric layers 135 and gate electrodes 130 may be formed, and gate isolation regions MS may be formed.

First, a first horizontal conductive layer 102 may be formed by depositing a conductive material on the horizontal tunnel portion HTL, and the sacrificial spacer layers SP may be removed from the trenches OP. Accordingly, a source structure SS including the plate layer 101 and the first and second horizontal conductive layers 102 and 104 may be formed.

The sacrificial insulating layers 118 may be selectively removed with respect to the interlayer insulating layers 120 using, for example, wet etching. Accordingly, a plurality of tunnel portions may be formed between the interlayer insulating layers 120. Gate dielectric layers 135 may be formed by depositing an insulating material on the plurality of tunnel portions, and gate electrodes 130 may be formed by depositing a conductive material. The conductive material may include a metal, polycrystalline silicon or metal silicide material.

After forming the gate dielectric layers 135 and the gate electrodes 130, by removing the conductive material deposited in the trenches OP through an additional process and forming the gate isolation insulating layer 105, the gate isolation regions MS may be formed.

Thereafter, and referring to FIGS. 2 and 16, by forming studs 170 that extend through the cell region insulating layer 190 and are connected to the channel structures CH and forming bit lines 180 on the studs 170, the semiconductor device 100 may be manufactured.

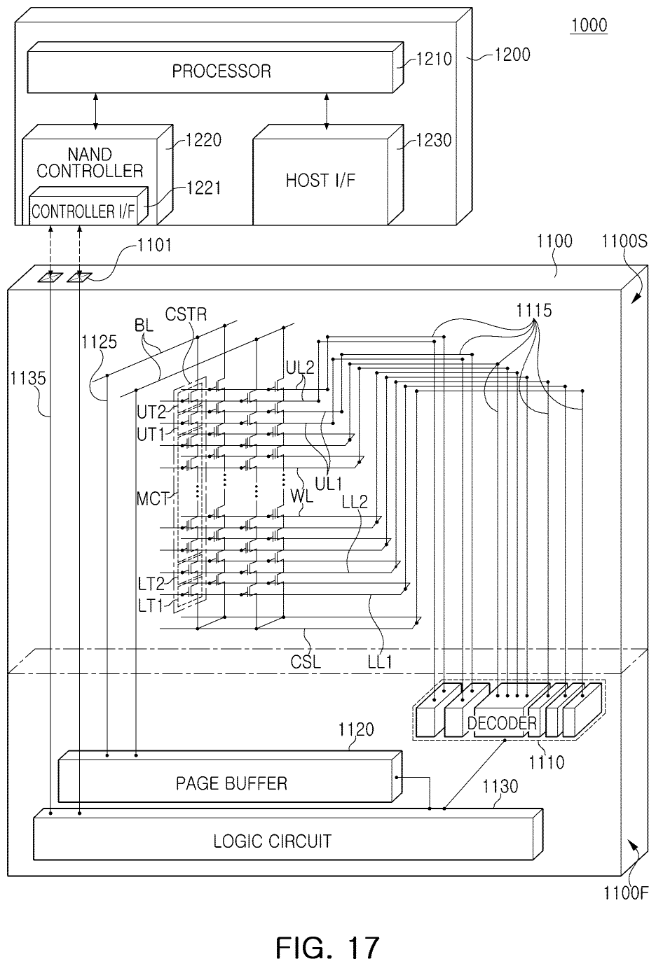

FIG. 17 is a view illustrating a data storage system including a semiconductor device according to an example embodiment.

Referring to FIG. 17, a data storage system 1000 may include a semiconductor device 1100 and a controller 1200 electrically connected to the semiconductor device 1100. The data storage system 1000 may be implemented as a storage device including one or a plurality of semiconductor devices 1100 or an electronic device including a storage device. For example, the data storage system 1000 may be implemented as a solid state drive device (SSD) including one or a plurality of semiconductor devices 1100, a universal serial bus (USB), a computing system, a medical device, or a communication device.

The semiconductor device 1100 may be implemented as a non-volatile memory device, such as, for example, the NAND flash memory device described in the aforementioned example embodiment with reference to FIGS. 1 to 6B. The semiconductor device 1100 may include a first structure 1100F and a second structure 1100S on the first structure 1100F. In the example embodiments, the first structure 1100F may be on the side of the second structure 1100S. The first structure 1100F may be implemented as a peripheral circuit structure including a decoder circuit 1110, a page buffer 1120, and a logic circuit 1130. The second structure 1100S may be implemented as a memory cell structure including a bit line BL, a common source line CSL, word lines WL, first and second gate upper lines UL1 and UL2, first and second gate lower lines LL1 and LL2 and memory cell strings CSTR between the bit line BL and the common source line CSL.

In the second structure 1100S, each of the memory cell strings CSTR may include lower transistors LT1 and LT2 adjacent to the common source line CSL, upper transistors UT1 and UT2 adjacent to the bit line BL, and a plurality of memory cell transistors MCT between the lower transistors LT1 and LT2 and the upper transistors UT1 and UT2. The number of lower transistors LT1 and LT2 and the number of upper transistors UT1 and UT2 may vary in other embodiments.

In the example embodiments, the upper transistors UT1 and UT2 may include a string select transistor, and the lower transistors LT1 and LT2 may include a ground select transistor. The gate lower lines LL1 and LL2 may be gate electrodes of the lower transistors LT1 and LT2, respectively. The word lines WL may be gate electrodes of the memory cell transistors MCT, and the gate upper lines UL1 and UL2 may be gate electrodes of the upper transistors UT1 and UT2, respectively.

In the example embodiments, the lower transistors LT1 and LT2 may include a lower erase control transistor LT1 and a ground select transistor LT2 connected to each other in series. The upper transistors UT1 and UT2 may include a string select transistor UT1 and an upper erase control transistor UT2 connected to each other in series. At least one of the lower erase control transistor LT1 and the upper erase control transistor UT2 may be used in an erase operation for erasing data stored in the memory cell transistors MCT using a GIDL phenomenon.

The common source line CSL, the first and second gate lower lines LL1 and LL2, the word lines WL, and the first and second gate upper lines UL1 and UL2 may be electrically connected to the decoder circuit 1110 through first connection interconnections 1115 extending from the first structure 1100F to the second structure 1100S. The bit lines BL may be electrically connected to the page buffer 1120 through second connection interconnections 1125 extending from the first structure 110F to the second structure 1100S.

In the first structure 1100F, the decoder circuit 1110 and the page buffer 1120 may perform a control operation on at least one selected memory cell transistor among the plurality of memory cell transistors MCT. The decoder circuit 1110 and the page buffer 1120 may be controlled by the logic circuit 1130. The semiconductor device 1100 may communicate with the controller 1200 through the input/output pad 1101 electrically connected to the logic circuit 1130. The input/output pads 1101 may be electrically connected to the logic circuit 1130 through an input/output connection line 1135 extending from the first structure 1100F to the second structure 1100S.

The controller 1200 may include a processor 1210, a NAND controller 1220, and a host interface 1230. In the example embodiments, the data storage system 1000 may include a plurality of semiconductor devices 1100, and in this case, the controller 1200 may control the plurality of semiconductor devices 1100.

The processor 1210 may control overall operation of the data storage system 1000 including the controller 1200. The processor 1210 may operate according to a predetermined firmware, and may access the semiconductor device 1100 by controlling the NAND controller 1220. The NAND controller 1220 may include a controller interface 1221 processing communication with the semiconductor device 1100. Through the controller interface 1221, a control command for controlling the semiconductor device 1100, data to be written to the memory cell transistors MCT of the semiconductor device 1100, and data to be read from the memory cell transistors MCT of the semiconductor device 1100 may be transmitted. The host interface 1230 may provide a communication function between the data storage system 1000 and an external host. When a control command from an external host is received through the host interface 1230, the processor 1210 may control the semiconductor device 1100 in response to the control command.

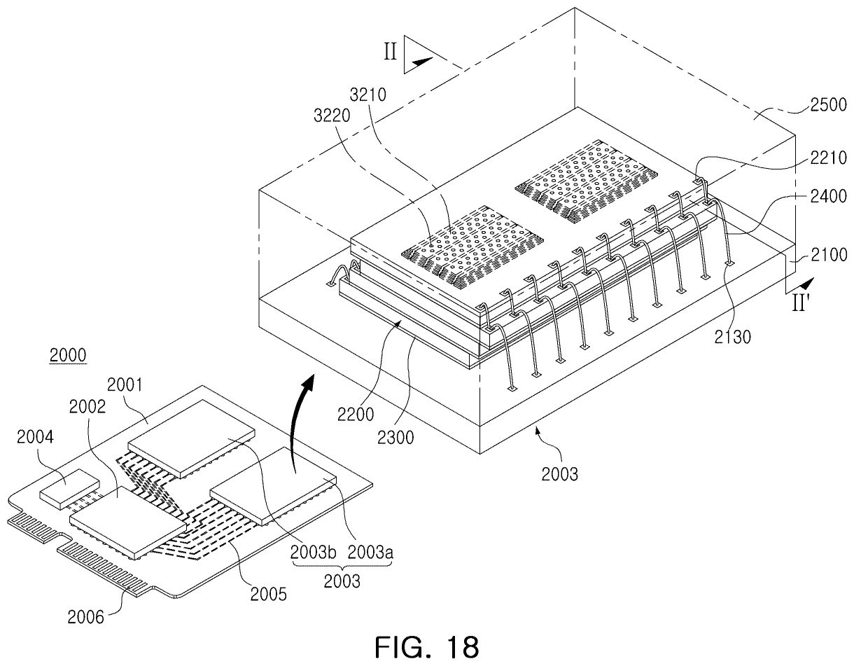

FIG. 18 is a perspective view illustrating a data storage system including a semiconductor device according to an example embodiment.

Referring to FIG. 18 a data storage system 2000 in an example embodiment may include a main board 2001, a controller 2002 mounted on the main board 2001, one or more semiconductor packages 2003, and a DRAM 2004. The semiconductor package 2003 and the DRAM 2004 may be connected to the controller 2002 by interconnection patterns 2005 formed on the main board 2001.

The main board 2001 may include a connector 2006 including a plurality of pins coupled to an external host. The number and arrangement of the plurality of pins in the connector 2006 may vary depending on a communication interface between the data storage system 2000 and the external host. In the example embodiments, the data storage system 2000 may communicate with an external host according to one of interfaces from among universal serial bus (USB), peripheral component interconnect express (PCI-Express), serial advanced technology attachment (SATA), M-Phy for universal flash storage (UFS). In the example embodiments, the data storage system 2000 may operate by power supplied from an external host through the connector 2006. The data storage system 2000 may further include a power management integrated circuit (PMIC) for distributing power supplied from the external host to the controller 2002 and the semiconductor package 2003.

The controller 2002 may write data to or may read data from the semiconductor package 2003, and may improve an operating speed of the data storage system 2000.

The DRAM 2004 may be a buffer memory for alleviating a difference in speeds between the semiconductor package 2003, which is a data storage space, and an external host. The DRAM 2004 included in the data storage system 2000 may operate as a cache memory, and may provide a space for temporarily storing data in a control operation for the semiconductor package 2003. When the data storage system 2000 may include the DRAM 2004, the controller 2002 may further include a DRAM controller for controlling the DRAM 2004 in addition to the NAND controller for controlling the semiconductor package 2003.

The semiconductor package 2003 may include first and second semiconductor packages 2003a and 2003b spaced apart from each other. Each of the first and second semiconductor packages 2003a and 2003b may be a semiconductor package including a plurality of semiconductor chips 2200. Each of the first and second semiconductor packages 2003a and 2003b may include a package substrate 2100, semiconductor chips 2200 on the package substrate 2100, adhesive layers 2300 on lower surfaces of the semiconductor chips 2200, respectively, a connection structure 2400 electrically connecting the semiconductor chips 2200 to the package substrate 2100, and a molding layer 2500 covering or overlapping the semiconductor chips 2200 and the connection structure 2400 on the package substrate 2100.

The package substrate 2100 may be a printed circuit board including package upper pads 2130. Each semiconductor chip 2200 may include an input/output pad 2210. The input/output pad 2210 may correspond to the input/output pad 1101 in FIG. 17. Each of the semiconductor chips 2200 may include gate stack structures 3210 and channel structures 3220. Each of the semiconductor chips 2200 may include the semiconductor device described in the aforementioned example embodiment with reference to FIGS. 1 to 6B.

In the example embodiments, the connection structure 2400 may be a bonding wire electrically connecting the input/output pad 2210 to the upper package pads 2130. Accordingly, in each of the first and second semiconductor packages 2003a and 2003b, the semiconductor chips 2200 may be electrically connected to each other by a bonding wire method, and may be electrically connected to the package upper pads 2130 of the package substrate 2100. In the example embodiments, and in each of the first and second semiconductor packages 2003a and 2003b, the semiconductor chips 2200 may be electrically connected to each other by a connection structure including a through-electrode (TSV) instead of the connection structure 2400 of a bonding wire method.

In the example embodiments, the controller 2002 and the semiconductor chips 2200 may be included in a single package. In an example embodiment, the controller 2002 and the semiconductor chips 2200 may be mounted on an interposer substrate different from the main board 2001, and the controller 2002 and the semiconductor chips 2200 may be connected to each other by interconnection formed on the interposer substrate.

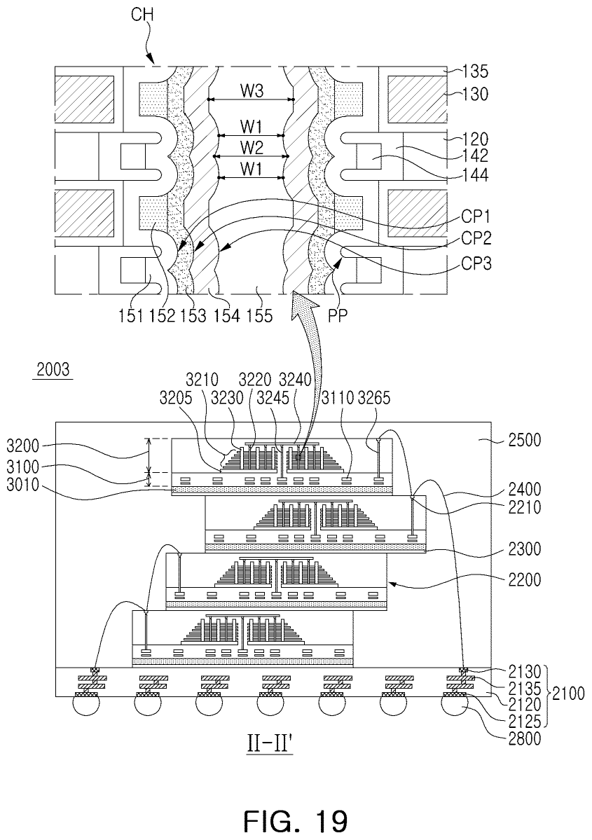

FIG. 19 is a cross-sectional view illustrating a semiconductor package according to an example embodiment, illustrating an example embodiment of the semiconductor package 2003 in FIG. 18 taken along line II-II′.

Referring to FIG. 19, in the semiconductor package 2003, the package substrate 2100 may be implemented as a printed circuit substrate. The package substrate 2100 may include a package substrate body portion 2120, package upper pads 2130 on an upper surface of the package substrate body portion 2120 (see FIG. 18), lower pads 2125 on the lower surface of the package substrate body 2120 or exposed through the lower surface, and internal interconnections 2135 electrically connecting the upper pads 2130 to the lower pads 2125 in the package substrate body 2120. The lower pads 2125 may be connected to the wiring patterns 2005 of the main the substrate 2001 of the data storage system 2000 through the conductive connection portions 2800 as illustrated in FIG. 18.

Each of the semiconductor chips 2200 may include a semiconductor substrate 3010 and a first structure 3100 and a second structure 3200 sequentially stacked on the semiconductor substrate 3010. The first structure 3100 may include a peripheral circuit region including peripheral interconnections 3110. The second structure 3200 may include a common source line 3205, a gate stack structure 3210 on the common source line 3205, channel structures 3220 extending through the gate stack structure 3210, bit lines 3240 electrically connected to the channel structures 3220, and contact plugs 3235 electrically connected to the word lines WL (see FIG. 17) of the gate stack structure 3210. As described above with reference to FIGS. 1 to 6B, in each of the semiconductor chips 2200, the first dielectric layer 151, the second dielectric layer 153, and the channel layer 154 of the channel structure CH may include first to third convex portions CP1, CP2, and CP3, respectively. Accordingly, the channel filling layer 155 may have corresponding widths.

Each of the semiconductor chips 2200 may include a through-interconnection 3245 electrically connected to the peripheral interconnections 3110 of the first structure 3100 and extending into the second structure 3200. The through-interconnection 3245 may be on an external side of the gate stack structure 3210 and may extend through the gate stack structure 3210. Each of the semiconductor chips 2200 may further include an input/output pad 2210 (see FIG. 18) electrically connected to the peripheral interconnections 3110 of the first structure 3100.

According to the aforementioned example embodiments, in a channel structure in which charge storage layers are spaced apart from each other in the vertical direction, by optimizing the arrangement of insulating layers and dielectric layers, a semiconductor device having improved reliability and a data storage system including the same may be provided.

While the example embodiments have been illustrated and described above, it will be configured as apparent to those skilled in the art that modifications and variations could be made without departing from the scope of the present disclosure as defined by the appended claims.

What is claimed is:

1. A semiconductor device, comprising:
a plate layer;
gate electrodes that are on the plate layer, extend in a first direction that is perpendicular to an upper surface of the plate layer, and are spaced apart from each other;
interlayer insulating layers that are alternately stacked with the gate electrodes on the plate layer; and
a channel structure that extends into the gate electrodes and in the first direction,
wherein the channel structure comprises a channel filling layer that extends in the first direction, a channel layer that at least partially surrounds the channel filling layer, charge storage layers that are between the gate electrodes and the channel layer and spaced apart from each other in the first direction, a first dielectric layer between the gate electrodes and the charge storage layers, and a second dielectric layer between the channel layer and the charge storage layers,
wherein the channel layer includes first convex portions that extend toward the channel filling layer from a side surface of the channel layer that contacts the channel filling layer, and
wherein vertices of the first convex portions are at first levels in the first direction that are between each level of a pair of adjacent gate electrodes in the first direction.

2. The semiconductor device of claim 1, wherein the vertices of the first convex portions are adjacent to an upper end of each of the interlayer insulating layers and a lower end of each of the interlayer insulating layers.

3. The semiconductor device of claim 1, wherein the channel filling layer comprises a plurality of widths, and wherein the channel layer has a minimum width of the plurality of widths between the vertices of the first convex portions.

4. The semiconductor device of claim 1, wherein the second dielectric layer comprises second convex portions that extend from a side surface of the second dielectric layer toward the channel filling layer, wherein the side surface of the second dielectric layer contacts the channel layer.

5. The semiconductor device of claim 4, wherein the first dielectric layer comprises third convex portions that extend from a side surface of the first dielectric layer toward the second dielectric layer, wherein the side surface of the first dielectric layer contacts the second dielectric layer.

6. The semiconductor device of claim 1,
wherein each of the charge storage layers includes a first side surface that contacts the first dielectric layer and a second side surface that contacts the second dielectric layer, and
wherein a length of the first side surface is less than a length of the second side surface.

7. The semiconductor device of claim 1, wherein the first dielectric layer comprises a single layer that extends in the first direction, and the second dielectric layer comprises a single layer that extends in the first direction.

8. The semiconductor device of claim 1, further comprising:
first insulating layers between the interlayer insulating layers and the first dielectric layer; and
second insulating layers, wherein each second insulating layer of the second insulating layers comprises upper surfaces, lower surfaces, and first side surfaces that contact a respective first insulating layer of the first insulating layers.

9. The semiconductor device of claim 8, wherein the first insulating layers include protrusions that are on the upper surfaces of the second insulating layers and the lower surfaces of the second insulating layers, and wherein the protrusions extend toward the first dielectric layer.

10. The semiconductor device of claim 9, wherein vertices of the protrusions are at substantially a same level as a corresponding first level of the vertices of a corresponding first convex portion of the first convex portions.

11. The semiconductor device of claim 8,
wherein the interlayer insulating layers and the first insulating layers comprise hydrogen, and
wherein a concentration of hydrogen of the first insulating layers is less than a concentration of hydrogen of the interlayer insulating layers.

12. The semiconductor device of claim 8,
wherein the second insulating layers, the first dielectric layer, and the first insulating layers comprise carbon, and
wherein a concentration of carbon of the second insulating layers is greater than a concentration of carbon of the first insulating layers and a concentration of carbon of the first dielectric layer.

13. The semiconductor device of claim 1, further comprising:
gate dielectric layers that at least partially surround the gate electrodes,
wherein a length of a given charge storage layer of the charge storage layers in the first direction may be greater than or equal to a value obtained by subtracting a sum of twice a length of the first dielectric layer from a sum of a length of a respective gate electrode of the gate electrodes and twice a thickness of a respective gate dielectric layer of the gate dielectric layers.

14. The semiconductor device of claim 1, further comprising:
a first horizontal conductive layer and a second horizontal conductive layer, wherein the second horizontal conductive layer is between the plate layer and the gate electrodes, and
wherein the first horizontal conductive layer defines a recess portion that extends in the first direction and that contacts the channel layer.

15. A semiconductor device, comprising:
a plate layer;
gate electrodes that are on the plate layer, extend in a first direction that is perpendicular to an upper surface of the plate layer, and are spaced apart from each other;
interlayer insulating layers that are alternately stacked with the gate electrodes on the plate layer; and
a channel structure that extends into the gate electrodes and in the first direction, wherein the channel structure comprises a channel filling layer, a channel layer on the channel filling layer, a second dielectric layer on the channel layer, charge storage layers on the second dielectric layer, and first dielectric layers on the charge storage layers, and
wherein the channel filling layer comprises inwardly curved portions that extend toward an inside of the channel filling layer, and wherein a first level of a first curved portion of the curved portions is at a level equal to or adjacent to an upper end of a first interlayer insulating layer of the interlayer insulating layers, and wherein a second level of a second curved portion of the curved portions is at a level equal to or adjacent to a lower end of the first interlayer insulating layer the interlayer insulating layers.

16. The semiconductor device of claim 15, wherein the channel filling layer comprises a plurality of widths, wherein the channel layer comprises two points that define a minimum width of the plurality of widths, and wherein the two points are in a region that opposes each of the interlayer insulating layers.

17. The semiconductor device of claim 15,
wherein the first dielectric layers comprise a single layer between a pair of adjacent gate electrodes of the gate electrodes,
wherein the charge storage layers comprises a plurality of layers that are spaced apart from each other between the pair of adjacent gate electrodes, and
wherein the second dielectric layer comprises a single layer between the pair of adjacent gate electrodes.

18. The semiconductor device of claim 15,
wherein the channel layer includes convex portions that extend toward the channel filling layer from a side surface of the channel layer that contacts the channel filling layer, and
wherein vertices of the convex portions are at second levels between the upper end and the lower end of each of the interlayer insulating layers.

19. A data storage system, comprising:
a semiconductor storage device comprising a first semiconductor structure, a second semiconductor structure on the first semiconductor structure, and an input/output pad electrically connected to the first semiconductor structure; and
a controller connected to the semiconductor storage device through the input/output pad,
wherein the second semiconductor structure includes:
a plate layer;
gate electrodes that are on the plate layer, extend in a first direction that is perpendicular to an upper surface of the plate layer, and are spaced apart from each other;
interlayer insulating layers that are alternately stacked with the gate electrodes on the plate layer; and
a channel structure that extends into the gate electrodes and in the first direction, wherein the channel structure comprises a channel filling layer, a channel layer on the channel filling layer, a second dielectric layer on the channel layer, charge storage layers on the second dielectric layer, and first dielectric layers on the charge storage layers,
wherein the channel layer includes convex portions that extend toward the channel filling layer from a side surface of the channel layer, and
wherein vertices of the convex portions are at first levels in the first direction that are levels between each level of a pair of adjacent gate electrodes in the first direction.

20. The data storage system of claim 19, wherein the vertices of the convex portions are in regions that oppose the interlayer insulating layers on the side surface of the channel layer.
